(19) United States
(12) Patent Application Publication
(10) Pub. No.: US 2025/0371215 A1
(43) Pub. Date: Dec. 4, 2025

(54) AVAILABLE TRANSFER CAPABILITY CALCULATION METHOD AND POWER TRANSACTION SYSTEM CONSIDERING REACTIVE POWER SUPPORT

(71) Applicant: SHANDONG UNIVERSITY, Jinan (CN)

(72) Inventors: Xiaoming Dong, Jinan (CN); Yuejian Wu, Jinan (CN); Chengfu Wang, Jinan (CN); Yong Wang, Jinan (CN); Tianguang Lv, Jinan (CN)

(73) Assignee: SHANDONG UNIVERSITY, Jinan (CN)

(21) Appl. No.: 19/298,247

(22) Filed: Aug. 13, 2025

Related U.S. Application Data
(63) Continuation-in-part of application No. 19/019,557, filed on Jan. 14, 2025.

(30) Foreign Application Priority Data
Apr. 18, 2024 (CN) 2024104697136

(51) Int. Cl. G06F 30/20

(52) U.S. Cl. CPC G06F 30/20

(57) ABSTRACT

An available transfer capability calculation method and system considering reactive power support includes: modeling and solving of power flow equations; establishment of reactive power optimization model based on mixed integer linear programming. Power system voltage regulation consisting of adjusting reactive power injection of generators, changing transformer taps and switching capacitors is included. The object of reactive power optimization is to get best voltage support by adjusting three types of control variables: adjusting reactive power injection of generators, changing transformer taps and switching capacitors. Available transfer capability is solved based on continuation power flow. In this invention, optimized adjustment of regulative resources like shunt capacitors, transformer taps and generators are comprehensively included in the process that power flow status gets close to transfer boundary.

### CROSS-REFERENCE TO RELATED APPLICATIONS

This application claims priority to U.S. Ser. No. 19/019,557 filed on 14 Jan. 2025 that claims priority to Chinese Patent Application Ser. No. CN 2024104697136 filed on 18 Apr. 2024.

### FIELD OF THE INVENTION

The present disclosure relates to power system steady state calculation and analysis. Based on conventional power flow model, considering optimized adjustment of power system regulative resources, and realizing reactive power optimization during the entire calculation procedure, the present disclosure proposes an available transfer capability calculation method and power transaction system considering reactive power support.

### BACKGROUND OF THE INVENTION

Available transfer capability (ATC) is an important technical indicator to measure the power exchanges limit from one point to another, which is widely applied in system operators like Pennsylvania-New Jersey-Maryland Interconnection (PJM) and California Independent System Operator Corporation (CAISO) in the United States. Transfer limit of power system is influenced by multiple factors like topological structure of the grid and operation status of all devices. So, in order to reduce network congestion and increase economic benefits in the power transaction process, system operators are always finding solutions to improve ATC calculation results by optimizing the operation status of the transmission system.

Continuation power flow is a common method to analysis available transfer capability of power systems, whose mathematical form is a power flow equation set in a prolonged form. For a given network, it continuously increases generation and load according to a fixed mode until power transfer limit is reached. ATC can be obtained by subtracting existing transmission commitments and reliability margin from the calculated incremental power, and power transaction model can be established under the restriction of ATC value.

Based on the aforementioned background, scholars worldwide has taken various research on the modeling and calculation of ATC. However, existing research achievements generally concentrate on the improvement of calculation methodologies, which lacks deeper understanding and innovative modeling of the process that power flow status gets close to operational boundary. Calculation process of ATC is accompanied by rising system load and declining voltage level, indicating the characteristic that system reactive power distribution turns to be unbalanced and inadequately supplied. Reactive power optimization, as a mathematical method to improve system voltage level, has great potential in fully utilizing regulative capability and improving ATC calculation results, which will eventually bring more economic benefits to electricity customers in the power transaction process.

### SUMMARY OF THE INVENTION

Concentrate on the drawbacks of existing technologies, the present disclosure considers optimized regulative resources adjustment in available transfer capability calculation and applies it into power transaction analysis, combining continuation power flow model with power flow calculation and reactive power optimization, thus proposing an available transfer capability calculation method and power transaction system considering reactive power support.

In the present disclosure, based on fundamental continuation power flow calculation method, optimized adjustment of regulative resources like shunt capacitors, transformer taps and generators are comprehensively included, and an available transfer capability calculation method and power transaction system considering reactive power support is proposed, which has great significance in precise evaluation of available transfer capability and bringing more economic benefits to electricity customers.

The present disclosure separates the computation procedure of available transfer capability considering reactive power support, into four parts: power flow calculation, reactive power optimization, continuation power flow and available-transfer-capability-based power transaction model. Numerical solution of power flow equations is obtained from newton method. Linear optimization model of regulative resources like shunt capacitors, transformer taps and voltage and reactive power of generators are deduced. Predictor-corrector algorithm to solve prolonged continuation power flow is designed, which solves the problem that Jacobian matrix becomes singular near steady state voltage stability limit. The value of ATC is calculated according to the result of continuation power flow. Electricity price and transaction amount for generators and consumers are obtained under the restriction of ATC value. A simple 2 bus system is taken as example to calculate ATC and solve the power transaction problem based on the present disclosure, validating the effectiveness of the model.

A solving system of available-transfer-capability-based power transaction method considering reactive power support is also put forward in the present disclosure.

Terminology explanation:
Node: Component to collect, exchange and transfer electric power;
Branch: Component connecting nodes;
Load: Summarization of users' electric appliances;
Generator: Apparatus that generates electric power;
Power system: Entirety consisting of nodes, branches, load and generators;
Auto Generation Control (AGC): According to unbalanced power derived from power flow calculation, adjustment of active power setting value for generators;
Power transaction: Solve electricity price and decide the trading volume of electric power of generators and customers.

The technical proposal of the present disclosure is:
An available transfer capability and power transaction calculation method, including:
Modeling and solving power flow equations.

Reactive power optimization model based on mixed integer linear programming is established, including: power system voltage regulation consists of adjusting reactive power injection of generators, changing transformer taps and switching capacitors. The object of reactive power optimization is to get best voltage support by adjusting three types of control variables: adjusting reactive power injection of generators, changing transformer taps and switching capacitors.

Solve available transfer capability by continuation power flow.

Obtain electricity price and transaction amount for generators and consumers under the restriction of available transfer capability.

Preferably, in the present disclosure, modeling and solving power flow equations includes:

Acquiring improved power flow formulations, as shown below:

$$\{ \begin{matrix}{f}^{P} = \{ {P}_{i} - {\sum }_{j = 1}^{NB} {V}_{i} {V}_{j} ( {G}_{ij} cos {θ}_{ij} + {B}_{ij} sin {θ}_{ij} ) = 0 ( i ∈ {Φ}^{Bus} ) \\ {f}^{Q} = \{ {Q}_{i} - {\sum }_{j = 1}^{NB} {V}_{i} {V}_{j} ( {G}_{ij} sin {θ}_{ij} - {B}_{ij} cos {θ}_{ij} ) = 0 ( i ∈ {Φ}^{Bus} )\end{matrix} \qquad ( 1 )$$

$$\{ \begin{matrix}{g}^{P} = \{ \begin{matrix}{P}_{ij}^{Bra} - {G}_{ij} ( {V}_{i}^{2} - {V}_{i} {V}_{j} cos {θ}_{ij} ) + {B}_{ij} {V}_{i} {V}_{j} sin {θ}_{ij} = 0 \\ ( ( i , j ) ∈ {Φ}^{Bra} )\end{matrix} \\ {g}^{Q} = \{ \begin{matrix}{Q}_{ij}^{Bra} - {B}_{ij} ( {V}_{i}^{2} - {V}_{i} {V}_{j} cos {θ}_{ij} ) + {G}_{ij} {V}_{i} {V}_{j} sin {θ}_{ij} = 0 \\ ( ( i , j ) ∈ {Φ}^{Bra} )\end{matrix}\end{matrix} \qquad ( 2 )$$

$$\{ \begin{matrix}{P}_{i} = {P}_{i 0} + μ {α}_{i} + λ {K}_{i}^{P} \\ {Q}_{i} = {Q}_{i 0} + λ {K}_{ι}^{Q}\end{matrix} \qquad ( 3 )$$

Where, f^{P} and f^{Q} represent active power and reactive power balance equations. g^{P} and g^{Q} represent equations for active power and reactive power of branches. Pᵢ and Qᵢ are active and reactive power injections at bus i, while Pᵢ₀ and Qᵢ₀ are Pᵢ and Qᵢ at initial PF state.

$${P}_{ij}^{Bra} and {Q}_{ij}^{Bra}$$

are active and reactive power flow carried by branch (i, j). Vᵢ is voltage magnitude at bus i. μ is the level of system unbalance power caused by power loss. αᵢ is AGC participating coefficient for generation bus i to handle the unbalance power. θᵢⱼ is the phase angle between complex bus voltages Vᵢ and Vⱼ. NB is the total bus count of the network. Gᵢᵢ and Bᵢᵢ are self-conductance and self-susceptance at bus i. Gᵢⱼ and Bᵢⱼ represent mutual conductance mutual susceptance between buses i and j. Φ^{Bus} represent collections of all system buses. Φ^{Bra} represent collections of all system branches. λ represents power incremental parameter, while

$${K}_{i}^{P} and {K}_{i}^{Q}$$

are active and reactive power increase coefficients for the bus i relative to λ.

Under certain system operation mode, the AGC participating coefficients are generally specified as constants which can be expressed as relation (4):

$$A = {[ \begin{matrix}{α}_{1} & {α}_{2} & L & {α}_{n}\end{matrix} ]}^{T} ( {\sum }_{i = 1}^{n} {α}_{i} = 1 ; {α}_{i} \geq 0 ) \qquad ( 4 )$$

Where, A is the vector of unbalanced power proportion.

Compact from of equation (1) can be expressed by:

$$F ( X ) = 0 ( X = [ μ , θ , V ] ) \qquad ( 5 )$$

Where, θ is the vector of voltage phase angles except for the slack bus. V is the vector of voltage magnitudes.

Equation (5) is a nonlinear equation set, which can be solved by iterative algorithms. Newton iterative relations shown in (6) are established.

$$\{ \begin{matrix}F ( {X}^{( s )} ) = ( \frac{\partial F ( X )}{\partial X} {\vert}_{x = {x}^{( s )}} ) {( Δ {X}^{( s )} )}^{T} = {{J}_{PF}^{( s )} ( Δ {X}^{( s )} )}^{T} \\ {X}^{( s + 1 )} = {X}^{( s )} - Δ {X}^{( s )}\end{matrix} \qquad ( 6 )$$

Where, s and (s+1) represent the number of iterations. X^{(s)} the value of X in s^{th} iteration.

The structure of Jacobian matrix

$${J}_{PF}^{( s )}$$

in (6) is elaborated as shown in (7).

$${J}_{PF}^{( s )} = ( \begin{matrix}A & \frac{\partial {f}^{P}}{\partial θ} & \frac{\partial {f}^{P}}{\partial V} \\ 0 & \frac{\partial {f}^{Q}}{\partial θ} & \frac{\partial {f}^{Q}}{\partial V}\end{matrix} ) {\vert}_{x = {x}^{( s )}} \qquad ( 7 )$$

Derivative of active power equations to unbalanced power is A. Derivative of active and reactive power equations to phase angles and voltage magnitudes are shown in (8)-(11).

$$\frac{\partial {f}_{i}^{P}}{\partial {θ}_{j}} = \{ \begin{matrix}{V}_{i}^{2} {B}_{ii} + {Q}_{i} ( i = j ) \\ - {V}_{i} {V}_{j} ( {G}_{ij} sin {θ}_{ij} - {B}_{ij} cos {θ}_{ij} ) ( else )\end{matrix} \qquad ( 8 )$$

$$\frac{\partial {f}_{i}^{P}}{\partial {V}_{j}} = \{ \begin{matrix}{V}_{i}^{2} {G}_{ii} + {P}_{i} ( i = j ) \\ - {V}_{i} {V}_{j} ( {G}_{ij} cos {θ}_{ij} + {B}_{ij} sin {θ}_{ij} ) ( else )\end{matrix} \qquad ( 9 )$$

$$\frac{\partial {f}_{i}^{Q}}{\partial {θ}_{j}} = \{ \begin{matrix}{V}_{i}^{2} {G}_{ii} - {P}_{i} ( i = j ) \\ {V}_{i} {V}_{j} ( {G}_{ij} cos {θ}_{ij} + {B}_{ij} sin {θ}_{ij} ) ( else )\end{matrix} \qquad ( 10 )$$

$$\frac{\partial {f}_{i}^{P}}{\partial {V}_{j}} = \{ \begin{matrix}{V}_{i}^{2} {B}_{ii} - {Q}_{i} ( i = j ) \\ - {V}_{i} {V}_{j} ( {G}_{ij} sin {θ}_{ij} - {B}_{ij} cos {θ}_{ij} ) ( else )\end{matrix} \qquad ( 11 )$$

Where,

$${f}_{i}^{P} and {f}_{i}^{Q}$$

represent active power and reactive power balance equations of bus i. Pᵢ and Qᵢ are active and reactive power injections at bus i. Vᵢ is voltage magnitude at bus i. θᵢ symbolizes phase angel at bus i. θᵢⱼ is the phase angle between bus i and j. Gᵢᵢ and Bᵢᵢ are self-conductance and self-susceptance at bus i. Gᵢⱼ and Bᵢⱼ represent mutual conductance mutual susceptance between buses i and j.

Convergence principle of Newton method is elaborated in (12).

$${ε}^{PF} = {‖ F ( X ) ‖}_{∞} \qquad ( 12 )$$

Considering the infinite norm of F(X), ε^{PF}, when ε^{PF} is less than a small enough positive (ε^{PF}<ε^{min}), the Newton iterations converge. Moreover, divergence takes place if ε^{PF} exceeds an allowable level (ε^{PF}>ε^{max}). ε^{min} and ε^{max} are parameters for judging convergence and divergence of Newton method.

Preferably, in the present disclosure, establishment of reactive power optimization model based on mixed integer linear programming includes:

Objective function of reactive power optimization model is minimizing active power flow, or reducing unbalanced power Δμ, as shown in (13).

$$Min Δμ \qquad ( 13 )$$

Equality constraints of reactive power optimization are equation (1) and (2), which is a nonlinear equation set. Substitute nonlinear equality constraints with linear ones, which are demonstrated in (14)-(16)

$${[ {J}_{OPF} {\vert}_{x = {x}^{( sc )}} ] [ Δ Z ]}^{T} = 0 \qquad ( 14 )$$

$${J}_{OPF} = [ \begin{matrix}A & \frac{\partial {f}^{P}}{\partial θ} & \frac{\partial {f}^{P}}{\partial V} & \frac{\partial {f}^{P}}{\partial {Q}^{G}} & \frac{\partial {f}^{P}}{\partial T} & \frac{\partial {f}^{P}}{\partial S} & 0 & 0 \\ 0 & \frac{\partial {f}^{Q}}{\partial θ} & \frac{\partial {f}^{Q}}{\partial V} & \frac{\partial {f}^{Q}}{\partial {Q}^{G}} & \frac{\partial {f}^{Q}}{\partial T} & \frac{\partial {f}^{Q}}{\partial S} & 0 & 0 \\ 0 & \frac{\partial {g}^{P}}{\partial θ} & \frac{\partial {g}^{P}}{\partial V} & 0 & \frac{\partial {g}^{P}}{\partial T} & 0 & E & 0 \\ 0 & \frac{\partial {g}^{Q}}{\partial θ} & \frac{\partial {g}^{Q}}{\partial V} & 0 & \frac{\partial {g}^{Q}}{\partial T} & 0 & 0 & E\end{matrix} ] \qquad ( 15 )$$

$$Δ Z = [ \begin{matrix}Δμ & Δ θ & ΔV & Δ {Q}^{G} & Δ T & Δ S & Δ {P}^{Bra} & Δ {Q}^{Bra}\end{matrix} ] \qquad ( 16 )$$

Where, Z denotes the vector of all the power flow state and control variables. T is the vector of the transformer tap position for all the on-load tap changers (OLTC). Q^{G} indicates reactive power injections at generation buses. P^{Bra} and Q^{Bra} represent the set of

$${P}_{ij}^{Bra} and {Q}_{ij}^{Bra} .$$

E represents unit matrix.

The relations in (17)-(23) show the inequality constraints for reactive power optimization:

$${V}_{i} - {V}_{i}^{min} \leq Δ {V}_{i} \leq {V}_{i} - {V}_{i}^{max} ( i ∈ {Φ}^{B u s} ) \qquad ( 17 )$$

$${Q}_{i}^{min} - {Q}_{i} \leq Δ {Q}_{i} \leq {Q}_{i}^{max} - {Q}_{i} ( i ∈ {Φ}^{G e n} ) \qquad ( 18 )$$

$${T}_{i}^{min} - {T}_{i} \leq Δ {T}_{i} \leq {T}_{i}^{max} - {T}_{i} ( i ∈ {Φ}^{T r a n s} ) \qquad ( 19 )$$

$$max ( 0 - {S}_{i} , - 1 ) \leq Δ {S}_{i} \leq min ( {S}_{i}^{max} - {S}_{i} , 1 ) ( i ∈ {Φ}^{S hunt} ) \qquad ( 20 )$$

$${( {P}_{ij}^{B r a} + Δ {P}_{ij}^{B r a} )}^{2} + {( {Q}_{ij}^{B r a} + Δ {Q}_{ij}^{B r a} )}^{2} \leq {( {S}_{ij}^{max} )}^{2} ( ( i , j ) ∈ {Φ}^{B r a} ) \qquad ( 21 )$$

$${\underline{{ϕ}_{i}}}^{V} \leq Δ {V}_{i} \leq {\overline{{ϕ}_{1}}}^{V} ( i ∈ {Φ}^{G e n} ) \qquad ( 22 )$$

$${\underline{{ϕ}_{i}}}^{Q} \leq Δ {Q}_{i} \leq {\overline{{ϕ}_{i}}}^{Q} ( i ∈ {Φ}^{G e n} ) \qquad ( 23 )$$

Where, Vᵢ is voltage magnitude at bus i.

$${V}_{i}^{max} and {V}_{i}^{min}$$

are maximum and minimum voltage magnitudes at bus i. Φ^{Bus} represent collections of all system buses. Qᵢ is reactive power injection at bus i.

$${Q}_{i}^{max} and {Q}_{i}^{min}$$

are upper and lower limits of Qᵢ at generation bus i. Φ^{Gen} is the subset of generations buses. Tᵢ is the transformer tap position of the ith OLTC, of which upper and lower limits marked

$${T}_{i}^{max} and {T}_{i}^{min} .$$

Φ^{Trans} indicates the set of OLTCs. Sᵢ is the number of shunt capacitors deployed at bus i, of which upper bound is

$${S}_{i}^{max} .$$

Φ^{Shunt} represents the set of system buses deployed with compensators.

$${P}_{i j}^{Bra} and {Q}_{i j}^{B r a}$$

are active and reactive power flow carried by branch (i, j).

$${S}_{ij}^{max}$$

represents power flow limit of branch (i, j). Φ^{Bra} represent collections of all system branches.

$${\underline{{ϕ}_{i}}}^{V} , {\overline{{ϕ}_{i}}}^{V}$$

are optimization step upper and lower limit for voltage magnitude at generation bus i.

$${\underline{{ϕ}_{i}}}^{G} , {\overline{{ϕ}_{i}}}^{G}$$

are optimization step upper and lower limit for reactive power injection at generation bus i.

Further preferably, derivative of branch power flow to voltage magnitudes and phase angles are demonstrated in (24)-(27):

$$\{ \begin{matrix}\frac{\partial {g}_{ij}^{P}}{\partial {V}_{i}} = - 2 {G}_{ij} {V}_{i} + {G}_{ij} {V}_{j} cos {θ}_{ij} + {B}_{ij} {V}_{j} sin {θ}_{ij} \\ \frac{\partial {g}_{ij}^{P}}{\partial {V}_{j}} = {G}_{ij} {V}_{i} cos {θ}_{ij} + {B}_{ij} {V}_{i} sin {θ}_{ij}\end{matrix} ( ( i , j ) ∈ {Φ}^{Bra} ) \qquad ( 24 )$$

$$\{ \begin{matrix}\frac{\partial {g}_{ij}^{Q}}{\partial {V}_{i}} = 2 {B}_{ij} {V}_{i} - {B}_{ij} {V}_{j} cos {θ}_{ij} + {G}_{ij} {V}_{j} sin {θ}_{ij} \\ \frac{\partial {g}_{ij}^{Q}}{\partial {V}_{i}} = - {B}_{ij} {V}_{i} cos {θ}_{ij} + {G}_{ij} {V}_{i} sin {θ}_{ij}\end{matrix} ( ( i , j ) ∈ {Φ}^{Bra} ) \qquad ( 25 )$$

$$\{ \begin{matrix}\frac{\partial {g}_{ij}^{P}}{\partial {θ}_{i}} = - {G}_{ij} {V}_{i} {V}_{j} sin {θ}_{ij} + {B}_{ij} {V}_{i} {V}_{j} cos {θ}_{ij} \\ \frac{\partial {g}_{ij}^{P}}{\partial {θ}_{j}} = {G}_{ij} {V}_{i} {V}_{j} sin {θ}_{ij} - {B}_{ij} {V}_{i} {V}_{j} cos {θ}_{ij}\end{matrix} ( ( i , j ) ∈ {Φ}^{Bra} ) \qquad ( 26 )$$

$$\{ \begin{matrix}\frac{\partial {g}_{ij}^{Q}}{\partial {θ}_{i}} = {B}_{ij} {V}_{i} {V}_{j} sin {θ}_{ij} + {G}_{ij} {V}_{i} {V}_{j} cos {θ}_{ij} \\ \frac{\partial {g}_{ij}^{Q}}{\partial {θ}_{j}} = - {B}_{ij} {V}_{i} {V}_{j} sin {θ}_{ij} - {G}_{ij} {V}_{i} {V}_{j} cos {θ}_{ij}\end{matrix} ( ( i , j ) ∈ {Φ}^{Bra} ) \qquad ( 27 )$$

Where,

$${g}_{ij}^{P} and {g}_{ij}^{Q}$$

represent equations for active power and reactive power of branch (i, j). Vi is voltage magnitude at bus i. θᵢ symbolizes phase angle at bus i. θᵢⱼ is the phase angle between bus i and j. Gᵢᵢ and Bᵢᵢ are self-conductance and self-susceptance at bus i. Gᵢⱼ and Bᵢⱼ represent mutual conductance mutual susceptance between buses i and j. Φ^{Bra} represent collections of all system branches.

Further preferably, derivative to reactive power generation can be acquired by differentiating active and reactive power equations to reactive power injections, as shown in (28)-(29):

$$\frac{\partial {f}_{i}^{P}}{\partial {Q}_{j}^{G}} = 0 ( i , j ∈ {Φ}^{Gen} ) \qquad ( 28 )$$

$$\frac{\partial {f}_{i}^{Q}}{\partial {Q}_{j}^{G}} = \{ \begin{matrix}1 & ( i = j ; i , j ∈ {Φ}^{Gen} ) \\ 0 & ( else )\end{matrix} \qquad ( 29 )$$

Where,

$${f}_{i}^{P} and {f}_{i}^{Q}$$

represent active power and reactive power balance equations of bus i.

$${Q}_{j}^{G}$$

is reactive power injection at generation bus j. Φ^{Gen} is the subset of generations buses.

Further preferably, derivative to transformer taps, also the relationship between non-standard ratio of the transformer k and tap position T, is demonstrated in (30):

$$\begin{matrix}k = {k}_{0} ( 1 + {Tk}_{T} ) \\ ( {k}_{T} = 2.5 \% ; T ∈ \{ - 4 , - 3 , ... , 3 , 4 \} )\end{matrix} \qquad ( 30 )$$

Where, k₀ is rated non-standard ratio of the transformer. k_{T} indicates the variation of transformer ratio corresponding to one tap position change.

Differentiating k to T, relationship between dk and dT is shown in (31), which is applied in transition between derivative to k and T for further calculation.

$$\frac{dk}{dT} = {k}_{T} {k}_{0} \qquad ( 31 )$$

Listing the self and mutual admittance between bus i and j, as demonstrated in (32)-(34):

$${G}_{ii} + {jB}_{ii} = \frac{( k - 1 )}{k} {Y}_{T} + \frac{{Y}_{T}}{k} = \begin{matrix}{Y}_{T} & ( {Y}_{T} = {G}_{T} + {jB}_{T} )\end{matrix} \qquad ( 32 )$$

$${G}_{jj} + {jB}_{jj} = \frac{( k - 1 )}{{k}^{2}} {Y}_{T} + \frac{{Y}_{T}}{k} = \frac{{Y}_{T}}{{k}^{2}} \qquad ( 33 )$$

$${G}_{ij} + {jB}_{ij} = - \frac{{Y}_{T}}{k} \qquad ( 34 )$$

Differentiating (32)-(34) to T and plug in (31), we get:

$$\frac{\partial {G}_{ii}}{\partial T} = \frac{\partial {B}_{ii}}{\partial T} = 0 \qquad ( 35 )$$

$$\frac{\partial {G}_{ij}}{\partial T} + j \frac{\partial {B}_{ij}}{\partial T} = \frac{{k}_{0} {k}_{T}}{{k}^{2}} {G}_{T} + j \frac{{k}_{0} {k}_{T}}{{k}^{2}} {B}_{T} \qquad ( 36 )$$

$$\frac{\partial {G}_{jj}}{\partial T} + j \frac{\partial {B}_{jj}}{\partial T} = \frac{- 2 {k}_{0} {k}_{T}}{{k}^{3}} {G}_{T} + j \frac{- 2 {k}_{0} {k}_{T}}{{k}^{3}} {B}_{T} \qquad ( 37 )$$

Differentiating f^{P}, f^{Q}, g^{P} and g^{Q} to T and plug in (35)-(37), we get:

$$\{ \begin{matrix}\frac{\partial {f}_{i}^{P}}{\partial T} = - \frac{{k}_{0} {k}_{T}}{{k}^{2}} {V}_{i} {V}_{j} ( {G}_{T} cos {θ}_{ij} + {B}_{T} sin {θ}_{ij} ) \\ \frac{\partial {f}_{j}^{P}}{\partial T} = \frac{2 {k}_{0} {k}_{T}}{{k}^{3}} {G}_{T} {V}_{j}^{2} - \frac{{k}_{0} {k}_{T}}{{k}^{2}} {V}_{i} {V}_{j} ( {G}_{T} cos {θ}_{ij} - {B}_{T} sin {θ}_{ij} ) \\ \frac{\partial {f}_{i}^{Q}}{\partial T} = - \frac{{k}_{0} {k}_{T}}{{k}^{2}} {V}_{i} {V}_{j} ( {G}_{T} sin {θ}_{ij} - {B}_{T} cos {θ}_{ij} ) \\ \frac{\partial {f}_{j}^{Q}}{\partial T} = - \frac{2 {k}_{0} {k}_{T}}{{k}^{3}} {B}_{T} {V}_{j}^{2} + \frac{{k}_{0} {k}_{T}}{{k}^{2}} {V}_{i} {V}_{j} ( {G}_{T} sin {θ}_{ij} + {B}_{T} cos {θ}_{ij} )\end{matrix} ( i , j ∈ {Φ}^{B} ) \qquad ( 38 )$$

$$\{ \begin{matrix}\frac{\partial {g}_{ij}^{P}}{\partial T} = - \frac{{k}_{0} {k}_{T}}{{k}^{2}} {G}_{T} ( {V}_{i}^{2} - {V}_{i} {V}_{j} cos {θ}_{ij} ) + \frac{{k}_{0} {k}_{T}}{{k}^{2}} {B}_{T} {V}_{i} {V}_{j} sin {θ}_{ij} \\ \frac{\partial {g}_{ij}^{Q}}{\partial T} = \frac{{k}_{0} {k}_{T}}{{k}^{2}} {B}_{T} ( {V}_{i}^{2} - {V}_{i} {V}_{j} cos {θ}_{ij} ) + \frac{{k}_{0} {k}_{T}}{{k}^{2}} {G}_{T} {V}_{i} {V}_{j} sin {θ}_{ij}\end{matrix} ( ( i , j ) ∈ {Φ}^{Bra} ) \qquad ( 39 )$$

Where, k and k₀ are actual and rated non-standard ratio of the transformer. k_{T} indicates the variation of transformer ratio corresponding to one tap position change. Gᵢᵢ and Bᵢᵢ are self-conductance and self-susceptance at bus i. Gᵢⱼ and Bᵢⱼ represent mutual conductance mutual susceptance between buses i and j. Y_{T} represents the transformer series admittance.

$${f}_{i}^{P} and {f}_{i}^{Q}$$

represent active power and reactive power balance equations of bus i.

$${g}_{ij}^{P} and {g}_{ij}^{Q}$$

represent equations for active power and reactive power of branch (i, j). Vᵢ is voltage magnitude at bus i. θᵢⱼ is the phase angle between bus i and j.

Further preferably, derivative to shunt capacitors can be obtained by differentiating active and reactive power equations to S. We get:

$$\{ \begin{matrix}\frac{\partial {f}_{i}^{P}}{\partial {S}_{i}} = - \frac{\partial ( {V}_{i}^{2} ( {G}_{ii} cos {θ}_{ii} + {B}_{ii} sin {θ}_{ii} ) )}{\partial S} = 0 \\ \frac{\partial {f}_{i}^{Q}}{\partial {S}_{i}} = - \frac{\partial ( {V}_{i}^{2} ( {G}_{ii} sin {θ}_{ii} - {B}_{ii} cos {θ}_{ii} ) )}{\partial S} = {V}_{i}^{2} {B}_{S}\end{matrix} ( i ∈ {Φ}^{S} ) \qquad ( 40 )$$

Where,

$${f}_{i}^{P} and {f}_{i}^{Q}$$

represent active power and reactive power balance equations of bus i. Sᵢ is the number of shunt capacitors deployed at bus i. Gᵢᵢ and Bᵢᵢ are self-conductance and self-susceptance at bus i. θᵢⱼ is the phase angle between bus i and j. Vᵢ is voltage magnitude at bus i. B_{S} denotes compensator series susceptance.

Further preferably, linearization method of branch power flow constraints can be obtained by decoupling

$$Δ {P}_{ij}^{B r a} and {ΔQ}_{\dot{ij}}^{B r a} :$$

$$\begin{matrix}- {P}_{ij}^{Bra} - {P}_{ij}^{′} \leq Δ {P}_{ij}^{B r a} \leq - {P}_{ij}^{B r a} + {P}_{ij}^{′} \\ ( {P}_{ij}^{′} = \begin{matrix}\sqrt{{( {S}_{ij}^{max} )}^{2} - {( {Q}_{ij}^{Bra} )}^{2}} & ( ( i , j ) ∈ {Φ}^{Bra} )\end{matrix} )\end{matrix} \qquad ( 41 )$$

$$\begin{matrix}- {Q}_{ij}^{Bra} - {Q}_{ij}^{′} \leq Δ {Q}_{ij}^{B r a} \leq - {Q}_{ij}^{B r a} + {Q}_{ij}^{′} \\ ( {Q}_{ij}^{′} = \begin{matrix}\sqrt{{( {S}_{ij}^{max} )}^{2} - {( {P}_{ij}^{Bra} )}^{2}} & ( ( i , j ) ∈ {Φ}^{Bra} )\end{matrix} )\end{matrix} \qquad ( 42 )$$

Where,

$${P}_{i j}^{Bra} and {Q}_{i j}^{Bra}$$

are active and reactive power flow carried by branch (i, j).

$${S}_{i j}^{max}$$

represents power flow limit of branch (i, j). Φ^{Bra} represent collections of all system branches.

Further preferably, the regulation method of optimization step limit includes:

Define nonlinearity error χ as the principle of step size control, as shown in (43).

$${χ}^{( k )} = {μ}^{( k )} - {μ}^{best} \qquad ( 43 )$$

Where, χ^{(k)} is the error index. μ^{(k)} symbolizes unbalanced power acquired form power flow calculation after k^{th} reactive power optimization. μ^{best} is the minimum unbalanced power ever recorded in history.

When μ^{(k)} breaks the best record μ^{best}, step size is enlarged and μ^{best} is updated. Otherwise, it is reduced as shown (44)-(47).

$$= \{ \begin{matrix}{η}_{1} & ( {χ}^{( k )} > 0 ) \\ max ( {η}_{2} , {V}_{i}^{min} - {V}_{i} ) & ( {χ}^{( k )} \leq 0 )\end{matrix} \qquad ( 44 )$$

$${\overline{{ϕ}_{i}}}^{V ( k + 1 )} = \{ \begin{matrix}{η}_{1} {\overline{ϕ}}_{i}^{V ( k )} & ( {χ}^{( k )} > 0 ) \\ min ( {η}_{2} {ϕ}_{i}^{\overline{V} ( k )} , {V}_{i}^{max} - {V}_{i} ) & ( {χ}^{( k )} \leq 0 )\end{matrix} \qquad ( 45 )$$

$$= \{ \begin{matrix}{η}_{1} & ( {χ}^{( k )} > 0 ) \\ max ( {η}_{2} , {Q}_{i}^{min} - {Q}_{i} ) & ( {χ}^{( k )} \leq 0 )\end{matrix} \qquad ( 46 )$$

$${\overline{{ϕ}_{i}}}^{Q ( k + 1 )} = \{ \begin{matrix}{η}_{1} {\overline{ϕ}}_{i}^{Q ( k )} & ( {χ}^{( k )} > 0 ) \\ max ( {η}_{2} {\overline{ϕ}}_{i}^{Q ( k )} , {Q}_{i}^{max} - {Q}_{i} ) & ( {χ}^{( k )} \leq 0 )\end{matrix} \qquad ( 47 )$$

Where,

$$, {\overline{{ϕ}_{i}}}^{V}$$

are optimization step upper and lower limit for voltage magnitude at generation bus i.

$$, {\overline{{ϕ}_{i}}}^{G}$$

are optimization step upper and lower limit for reactive power injection at generation bus i. k is the number of iterations and χ^{(k)} is the error index. η₁ and η₂ are step adjustment parameters that satisfy 0<η₁<1<η₂. Vᵢ is voltage magnitude at bus i.

$${V}_{i}^{max} and {V}_{i}^{min}$$

are maximum and minimum voltage magnitudes at bus i. Qᵢ is reactive power injection at bus i.

$${Q}_{i}^{max} and {Q}_{i}^{min}$$

are upper and lower limits of Qᵢ at generation bus i.

Preferably, in the present disclosure, solution of available transfer capability based on continuation power flow includes:

As shown in (3), λ=0 represents original load and generation status. Power flow equations, or (3), can be regarded as parameterized equation about λ, whose geometric meaning is a curve in the solution space shown in (48):

$$F ( Y ) = F ( X , λ ) = 0 ( Y = [ μ θ V λ ] ) \qquad ( 48 )$$

To discover the limit of power flow transmission, trace along with the curve according to continuation power flow, through repetitive predictor and corrector steps, enlarging λ, so as to get voltage stability limit.

Before continuation power flow calculation, power growth mode of load and generation should be given in advance, with sum of

$${K}_{i}^{P} and {K}_{i}^{Q}$$

being 0, respectively as demonstrated in (49):

$$K = {[ {K}_{1}^{P} {K}_{2}^{P} L {K}_{NB}^{P} {K}_{1}^{Q} {K}_{2}^{Q} L {K}_{NB}^{Q} ]}^{T} ( {\sum }_{i = 1}^{NB} {K}_{i}^{P} = 0 ; {\sum }_{i = 1}^{NB} {K}_{b}^{Q} = 0 ) \qquad ( 49 )$$

Where, μ is the level of system unbalance power. θ is the vector of voltage phase angles except for the slack bus. V is the vector of voltage magnitudes. λ represents power incremental parameter. Y symbolizes continuation power flow solution vector.

$${K}_{i}^{P} and {K}_{i}^{Q}$$

are active and reactive power increase coefficients for the bus i relative to λ. NB is the total bus count of the network.

Further preferably, calculation method of predictor steps is shown below:

$${Y}^{p r e} = {Y}^{base} + σ \frac{d Y}{{‖ dY ‖}_{2}} \qquad ( 50 )$$

$$\{ \begin{matrix}{{J}_{CPF} [ dY ]}^{τ} = [ \begin{matrix}0 \\ 1\end{matrix} ] \\ {J}_{CPF} = [ \begin{matrix}{J}_{PF} & K \\ {e}_{c} & \end{matrix} ]\end{matrix}$$

$$( {e}_{c} = [ 0 L 010 L 0 ] ; c = \{ c ‖ {dy}_{c} \vert = {‖ dY ‖}_{∞} \} ) \qquad ( 51 )$$

Where, Y^{base} is original continuation power flow solution, and Y^{pre} represents the solution to be predicted. σ is step-size control coefficient. dY is tangent predictor vector, and ∥dY∥₂ is the second norm of dY. dY/∥dY∥₂ is the normalization of predictor step, thus σ represents actual step size regardless the modulus of dY. J_{CPF} marks the Jacobian matrix for continuation power flow calculation. J_{PF} symbolizes the Jacobian matrix for power flow calculation. K is the vector consisting of

$${K}_{i}^{P} and {K}_{i}^{Q} .$$

e_{c} is a vector for which the cth element is 1 while others are 0.

Recognition of bifurcation: Bifurcation is a sign where power system reaches voltage stability limit as the increase of λ, including two criterions, saddle node bifurcation and limit induced bifurcation.

Saddle node bifurcation represents the situation where λ is unable to increase further, whose criterion is dλ<0.

Limit induced bifurcation represents the situations where system reactive power reservation is exhausted, whose criterion is that there exists a bus whose VQ sensitivity is negative. If there exists at least one bus whose voltage magnitude declines along with the increase of reactive power injection, system voltage is unstable. Calculation method of minimum VQ sensitivity for each bus is listed in (52):

$${δ}^{min} = min \{ δ , \vert δ = {diag ( {J}_{CPF} )}^{- 1} , i ∈ {Φ}^{L} \} > 0 \qquad ( 52 )$$

Where, δᵢ is the VQ sensitivity of bus i. δ represents the vector of VQ sensitivity, which is also the diagonal elements of (J_{CPF})⁻¹. δ^{min} is the minimum VQ sensitivity of all buses. Φ^{L} is the subset of load buses.

Corrector steps are as follows:

Due to the nonlinear feature of the curve, predicted solution is not on the curve F(Y), which requires local parameterization to get power flow solution as shown in (53).

$$G ( Y ) = \{ \begin{matrix}F ( Y ) = 0 \\ {y}_{c} - {y}_{c}^{pre} = 0\end{matrix} \qquad ( 53 )$$

Where, Y symbolizes continuation power flow solution vector. G is the equation set of continuation power flow. y_{c} is the prolonged factor and

$${y}_{c}^{pre}$$

is y_{c} obtained from predictor steps.

Solution of (53) is similar with power flow calculation, as shown in (54), whose convergence criterion is given in (55):

$$\{ \begin{matrix}G ( {Y}^{( s )} ) = ( {J}_{CPF} {\vert}_{Y = {Y}^{( s )}} ) {( Δ {Y}^{( s )} )}^{T} = {{J}_{CPF}^{( s )} ( Δ {Y}^{( s )} )}^{T} \\ {Y}^{( s + 1 )} = {Y}^{( s )} + Δ {Y}^{( s )}\end{matrix} \qquad ( 54 )$$

$${ε}^{CPF} = {‖ G ( Y ) ‖}_{∞} \qquad ( 55 )$$

Where, Y symbolizes continuation power flow solution vector. G is the equation set of continuation power flow. s and (s+1) represent the number of iterations. Y^{(s)} the value of Y in s^{th} iteration. J_{CPF} marks the Jacobian matrix for continuation power flow calculation. ε^{CPF} is the infinite norm of G(X).

Select the number of iterations in corrector steps as the reference of adjusting step size σ, as shown in (56).

$$σ = \{ \begin{matrix}{β}_{1} σ & ( sc > ξ ) \\ {β}_{2} σ & ( sc \leq ξ )\end{matrix} \qquad ( 56 )$$

Where, sc is the number of iterations. ξ is a threshold concerning enlarging of decreasing step size. β₁ and β₂ are constants that satisfy 0<β₁<1<β₂.

Further preferably, available transfer capability is calculated below:

$${P}_{ATC} = {P}_{TTC} - {P}_{ETC} - {P}_{TRM} - {P}_{CBM} \qquad ( 57 )$$

Where, P_{ATC} is the available transfer capability for the transmission system. P_{TTC} is the total transfer capability of the transmission system. P_{ETC} is the sum of existing firm commitments for the transmission system. P_{TRM} is the transmission reliability margin for the transmission system. P_{CBM} is the capacity benefit margin for the transmission interface system.

As a simplification, in the present disclosure, the value of λ obtained from continuation power flow calculation is multiplied by 0.8 as available transfer capability. For more precise calculation of available transfer capability, users can refer to documents provided by PJM and CAISO.

Preferably, in the present disclosure, solution of electricity price and transaction amount for generators and consumers under the restriction of available transfer capability includes:

1) Objective function of the power transaction model is to maximize social welfare:

$$max F = {\sum }_{t = 1}^{T} {\sum }_{r = 1}^{R} S ( r , t ) {P}_{L} ( r , t ) - {\sum }_{t = 1}^{T} {\sum }_{g = 1}^{G} C ( g , t ) P ( g , t ) \qquad ( 58 )$$

Where, F symbolizes social welfare. S(r,t) is the bid price of the rth consumer. C(g,t) is the bid price of the gth generator. T is the number of trading periods. R is the number of consumers. G is the number of generators. P_{L}(r,t) is the traded electricity of the rth consumer at period t. P(g,t) is the traded electricity of the gth generator at period t.

2) Power balance constraints are given by:

$${\sum }_{g = 1}^{G} P ( g , t ) = {\sum }_{r = 1}^{R} {P}_{L} ( r , t ) + μ ( t ) , t = 1 , 2 , … , T \qquad ( 59 )$$

Where, G is the number of generators. R is the number of consumers. T is the number of trading periods. P(g,t) is the traded electricity of the gth generator at period t. P_{L}(r,t) is the traded electricity of the rth consumer at period t. μ(t) is power loss of the system at period t.

3) Output constraints for generators are shown below:

$${P}_{g , min} \leq P ( g , t ) \leq {P}_{g , max} , g = 1 , 2 , … , G , t = 1 , 2 , … , T \qquad ( 60 )$$

Where, P(g,t) is the traded electricity of the gth generator at period t. ΔP_{g,min} and P_{g,max} are lower and upper limit of output of the gth generator. G is the number of generators. T is the number of trading periods.

4) Ramping constraints for generators are demonstrated in:

$$- Δ {P}_{g} \leq P ( g , t + 1 ) - P ( g , t ) \leq Δ {P}_{g} , g = 1 , 2 , … , G , t = 1 , 2 , … , T - 1 \qquad ( 61 )$$

Where, P(g,t) is the traded electricity of the gth generator at period t. ΔP_{g} is the maximum output variation for the gth generator in each period. G is the number of generators. T is the number of trading periods.

5) ATC constraint is demonstrated by:

$${P}_{i j} ( t ) \leq {P}_{ATC} , t = 1 , 2 , … , T - 1 \qquad ( 62 )$$

Where, Pᵢⱼ(t) is the power of transmission line between bus i and j at period t. P_{ATC} is the available transfer capability for the transmission system. T is the number of trading periods.

Solving the power transaction model above, electricity price and transaction amount for generators and consumers can be decided.

After the electricity price and trading volume of generators and customers are decided, power plants and customers sign electric power purchase contract with the system operator. At the agreed-upon time, power plants will produce electricity and get income according to the traded volume and price, and consumers will buy previously-decided amount of electric power at the traded price.

Determining demands of the consumers for electric power; and

Controlling output of the electric power of generators to meet demands of the consumers by optimizing adjustment of shunt capacitors, transformer taps, and enabling efficient and reliable movement of electrical energy

A computer device, comprising a memory and a processor, wherein the memory stores a computer program, and the processor executes the computer program to implement the steps of available transfer capability and power transaction calculation method considering reactive power support.

A computer readable storage medium, wherein the medium stores a computer program, and the program is executed by processor to implement the steps of available transfer capability and power transaction calculation method considering reactive power support.

A solving system of available-transfer-capability-based power transaction method considering reactive power support includes:

Power flow modeling and solving module, configured as: modeling and solving power flow equations:

Establishment of reactive power optimization modeling module, configured as: establish reactive power optimization model based on mixed integer linear programming, including: power system voltage regulation consists of adjusting reactive power injection of generators, changing transformer taps and switching capacitors. The object of reactive power optimization is to get best voltage support by adjusting three types of control variables: adjusting reactive power injection of generators, changing transformer taps and switching capacitors.

Available transfer capability calculation module, configured as: solving available transfer capability based on continuation power flow.

Power transaction calculation module, configured as: obtain electricity price and transaction amount for generators and consumers under the restriction of available transfer capability.

The present disclosure considers optimized regulative resources adjustment in the entire procedure of available transfer capability analysis, combining continuation power flow model with power flow calculation and reactive power optimization, thus proposing an available transfer capability and power transaction calculation method considering reactive power support. This method has following advantages:
1) In the process that power flow status gets close to transfer limit, optimized adjustment of regulative resources like shunt capacitors, transformer taps and generators are comprehensively included in the present disclosure. Optimization model fully utilizes the potential of coordinated operation of regulative resources, lifting the value of available transfer capability, preventing the conservativeness in electricity market transactions due to limited reactive power support. For electricity customers, electricity price can be reduced, saving the expenses of energy consumption. For power plants, power transmission can be realized with larger scale and lower cost, which means that generators with better efficiency can meet more electric power demands and have more income.
2) In the present disclosure, continuation power flow calculation method is designed based on predictor-corrector steps, preventing the problem that Jacobian matrix becomes singular as power flow status getting close to transfer boundary, guaranteeing the convergence of newton iteration. Available transfer capability can be calculated precisely with a relatively small calculation cost, and the calculation method has good numerical stability.

### BRIEF DESCRIPTION OF THE DRAWINGS

FIG. 1 is the schematic diagram of mathematical model and the equivalent circuit of transformer.

FIG. 2 is the schematic diagram of iterative relationship of branch power flow.

FIG. 3 is the structural diagram of 2 bus system.

FIG. 4 is the schematic diagram of available transfer capability calculation result.

FIG. 5 is the power transaction result of generators and consumers.

### DETAILED DESCRIPTION OF THE EMBODIMENTS

Following materials are further explanations to the present disclosure based on drawings and examples, but not limited to this.

### Example 1

An available transfer capability calculation method considering reactive power support, including:

Modeling and solving power flow equations:

Reactive power optimization model based on mixed integer linear programming is established, including: power system voltage regulation consists of adjusting reactive power injection of generators, changing transformer taps and switching capacitors. The object of reactive power optimization is to get best voltage support by adjusting three types of control variables: adjusting reactive power injection of generators, changing transformer taps and switching capacitors.

Solve available transfer capability by continuation power flow.

### Example 2

An available transfer capability calculation method considering reactive power support based on what example 1 has mentioned, which differs in: Modeling and solving power flow equations, including:

To investigate the variation of load and generator power, acquiring improved power flow formulations, as shown below:

$$\{ \begin{matrix}{f}^{P} = \{ {P}_{i} - {\sum }_{j = 1}^{N B} {V}_{i} {V}_{j} ( {G}_{ij} cos {θ}_{ij} + {B}_{ij} sin {θ}_{ij} ) = 0 ( i ∈ {Φ}^{Bus} ) \\ {f}^{Q} = \{ {Q}_{i} - {\sum }_{j = 1}^{N B} {V}_{i} {V}_{j} ( {G}_{ij} sin {θ}_{ij} - {B}_{ij} cos {θ}_{ij} ) = 0 ( i ∈ {Φ}^{Bus} )\end{matrix} \qquad ( 1 )$$

$$\{ \begin{matrix}{g}^{P} = \{ \begin{matrix}{P}_{i j}^{Bra} - {G}_{i j} ( {V}_{i}^{2} - {V}_{i} {V}_{j} cos {θ}_{i j} ) + {B}_{i j} {V}_{i} {V}_{j} sin {θ}_{i j} = 0 \\ ( ( i , j ) ∈ {Φ}^{Bra} )\end{matrix} \\ {g}^{Q} = \{ \begin{matrix}{Q}_{i j}^{Bra} - {B}_{i j} ( {V}_{i}^{2} - {V}_{i} {V}_{j} cos {θ}_{i j} ) + {G}_{i j} {V}_{i} {V}_{j} sin {θ}_{i j} = 0 \\ ( ( i , j ) ∈ {Φ}^{Bra} )\end{matrix}\end{matrix} \qquad ( 2 )$$

$$\{ \begin{matrix}{P}_{i} = {P}_{i 0} + μ {α}_{i} + λ {K}_{i}^{P} \\ {Q}_{i} = {Q}_{i 0} + λ {K}_{i}^{Q}\end{matrix} \qquad ( 3 )$$

Where, f^{P} and f^{Q} represent active power and reactive power balance equations. g^{P} and g^{Q} represent equations for active power and reactive power of branches. Pᵢ and Qᵢ are active and reactive power injections at bus i, while Pᵢ₀ and Qᵢ₀ are Pᵢ and Qᵢ at initial PF state.

$${P}_{i j}^{Bra} and {Q}_{i j}^{Bra}$$

are active and reactive power flow carried by branch (i, j). Vᵢ is voltage magnitude at bus i. μ is the level of system unbalance power caused by power loss. αᵢ is AGC participating coefficient for generation bus i to handle the unbalance power. θᵢⱼ is the phase angle between complex bus voltages Vᵢ and Vⱼ. NB is the total bus count of the network. Gᵢᵢ and Bᵢᵢ are self-conductance and self-susceptance at bus i. Gᵢⱼ and Bᵢⱼ represent mutual conductance mutual susceptance between buses i and j. Φ^{Bus} represent collections of all system buses. Φ^{Bra} represent collections of all system branches. λ represents power incremental parameter, while

$${K}_{i}^{P} and {K}_{i}^{Q}$$

are active and reactive power increase coefficients for the bus i relative to λ.

Generally, under certain system operation mode, the AGC participating coefficients are generally specified as constants which can be expressed as relation (4):

$$A = {[ {α}_{1} {α}_{2} L {α}_{n} ]}^{T} ( {\sum }_{i = 1}^{n} {α}_{i} = 1 ; {α}_{i} \geq 0 ) \qquad ( 4 )$$

Where, A is the vector of unbalanced power proportion.

Compact from of equation (1) can be expressed by:

$$F ( X ) = 0 ( X = [ μ , θ , V ] ) \qquad ( 5 )$$

Where, θ is the vector of voltage phase angles except for the slack bus. V is the vector of voltage magnitudes.

Equation (5) is a nonlinear equation set, which can be solved by iterative algorithms. Newton iterative relations shown in (6) are established.

$$\{ \begin{matrix}F ( {X}^{( s )} ) = ( \frac{\partial F ( X )}{\partial X} {\vert}_{X = {X}^{( s )}} ) {( Δ {X}^{( s )} )}^{T} = {{J}_{PF}^{( s )} ( Δ {X}^{( s )} )}^{T} \\ {X}^{( s + 1 )} = {X}^{( s )} - Δ {X}^{( s )}\end{matrix} \qquad ( 6 )$$

Where, s and (s+1) represent the number of iterations. X^{(s)} the value of X in s^{th} iteration.

The structure of Jacobian matrix

$${J}_{PF}^{( s )}$$

in (6) is elaborated as shown in (7).

$${J}_{PF}^{( s )} = ( \begin{matrix}A & \frac{\partial {f}^{P}}{\partial θ} & \frac{\partial {f}^{P}}{\partial V} \\ 0 & \frac{\partial {f}^{Q}}{\partial θ} & \frac{\partial {f}^{Q}}{\partial V}\end{matrix} ) {\vert}_{X = {X}^{( s )}} \qquad ( 7 )$$

Derivative of active power equations to unbalanced power is A. Derivative of active and reactive power equations to phase angles and voltage magnitudes are the same with conventional Jacobian matrix calculation method, which are shown in (8)-(11).

$$\frac{\partial {f}_{i}^{P}}{\partial {θ}_{j}} = \{ \begin{matrix}{V}_{i}^{2} {B}_{ii} + {Q}_{i} ( i = j ) \\ - {V}_{i} {V}_{j} ( {G}_{ij} sin {θ}_{ij} - {B}_{ij} cos {θ}_{ij} ) ( else )\end{matrix} \qquad ( 8 )$$

$$\frac{\partial {f}_{i}^{P}}{\partial {V}_{j}} = \{ \begin{matrix}{V}_{i}^{2} {G}_{ii} - {P}_{i} ( i = j ) \\ - {V}_{i} {V}_{j} ( {G}_{ij} cos {θ}_{ij} - {B}_{ij} sin {θ}_{ij} ) ( else )\end{matrix} \qquad ( 9 )$$

$$\frac{\partial {f}_{i}^{Q}}{\partial {θ}_{j}} = \{ \begin{matrix}{V}_{i}^{2} {G}_{ii} - {P}_{i} ( i = j ) \\ {V}_{i} {V}_{j} ( {G}_{ij} cos {θ}_{ij} - B sin {θ}_{ij} ) ( else )\end{matrix} \qquad ( 10 )$$

$$\frac{\partial {f}_{i}^{Q}}{\partial {V}_{j}} = \{ \begin{matrix}{V}_{i}^{2} {B}_{ii} + {Q}_{i} ( i = j ) \\ - {V}_{i} {V}_{j} ( {G}_{ij} sin {θ}_{ij} - {B}_{ij} cos {θ}_{ij} ) ( else )\end{matrix} \qquad ( 11 )$$

Where,

$${f}_{i}^{P} and {f}_{i}^{Q}$$

represent active power and reactive power balance equations of bus i. Pᵢ and Qᵢ are active and reactive power injections at bus i. Vᵢ is voltage magnitude at bus i. θᵢ symbolizes phase angel at bus i. θᵢⱼ is the phase angle between bus i and j. Gᵢᵢ and Bᵢᵢ are self-conductance and self-susceptance at bus i. Gᵢⱼ and Bᵢⱼ represent mutual conductance mutual susceptance between buses i and j.

Convergence principle of Newton method is elaborated in (12).

$${ε}^{PF} = {‖ F ( X ) ‖}_{∞} \qquad ( 12 )$$

Considering the infinite norm of F(X), ε^{PF}, when ε^{PF} is less than a small enough positive (ε^{PF}<ε^{min}), the Newton iterations converge. Moreover, divergence takes place if &PF exceeds an allowable level (ε^{PF}>ε^{max}). ε^{min} and ε^{max} are parameters for judging convergence and divergence of Newton method.

Establish reactive power optimization model based on mixed integer linear programming, including:

Due to the fact that unreasonable or improper reactive power support will cause increase of power system transmission losses, objective function of reactive power optimization model is minimizing active power flow, or reducing unbalanced power Δμ, as shown in (13).

$$Min Δμ \qquad ( 13 )$$

Equality constraints of reactive power optimization are equation (1) and (2), which is a nonlinear equation set. To establish mixed integer linear programming model, substitute nonlinear equality constraints with linear ones, which are demonstrated in (14)-(16)

$${[ {J}_{OPF} {\vert}_{X = {X}^{( sc )}} ] [ Δ Z ]}^{T} = 0 \qquad ( 14 )$$

$${J}_{OPF} = [ \begin{matrix}A & \frac{\partial {f}^{P}}{\partial θ} & \frac{\partial {f}^{P}}{\partial V} & \frac{\partial {f}^{P}}{\partial {Q}^{G}} & \frac{\partial {f}^{P}}{\partial T} & \frac{\partial {f}^{P}}{\partial S} & 0 & 0 \\ 0 & \frac{\partial {f}^{Q}}{\partial θ} & \frac{\partial {f}^{Q}}{\partial V} & \frac{\partial {f}^{Q}}{\partial {Q}^{G}} & \frac{\partial {f}^{Q}}{\partial T} & \frac{\partial {f}^{Q}}{\partial S} & 0 & 0 \\ 0 & \frac{\partial {g}^{P}}{\partial θ} & \frac{\partial {g}^{P}}{\partial V} & 0 & \frac{\partial {g}^{P}}{\partial T} & 0 & E & 0 \\ 0 & \frac{\partial {g}^{Q}}{\partial θ} & \frac{\partial {g}^{Q}}{\partial V} & 0 & \frac{\partial {g}^{Q}}{\partial T} & 0 & 0 & E\end{matrix} ] \qquad ( 15 )$$

$$Δ Z = [ \begin{matrix}Δμ & Δθ & ΔV & Δ {Q}^{G} & Δ T & Δ S & Δ {P}^{Bra} & Δ {Q}^{Bra}\end{matrix} ] \qquad ( 16 )$$

Where, Z denotes the vector of all the power flow state and control variables. T is the vector of the transformer tap position for all the on-load tap changers (OLTC). Q^{G} indicates reactive power injections at generation buses. P^{Bra} and Q^{Bra} represent the set of

$${P}_{ij}^{Bra} and {Q}_{ij}^{Bra} .$$

E represents unit matrix.

The relations in (17)-(23) show the inequality constraints for reactive power optimization:

$${V}_{i} - {V}_{i}^{min} \leq {ΔV}_{i} \leq {V}_{i} - {V}_{i}^{max} ( i ∈ {Φ}^{Bus} ) \qquad ( 17 )$$

$${Q}_{i}^{min} - {Q}_{i} \leq Δ {Q}_{i} \leq {Q}_{i}^{max} - {Q}_{i} ( i ∈ {Φ}^{Gen} ) \qquad ( 18 )$$

$${T}_{i}^{min} - {T}_{i} \leq Δ {T}_{i} \leq {T}_{i}^{max} - {T}_{i} ( i ∈ {Φ}^{Trans} ) \qquad ( 19 )$$

$$max ( 0 - {S}_{i} , - 1 ) \leq Δ {S}_{i} \leq min ( {S}_{i}^{max} - {S}_{i} , 1 ) ( i ∈ {Φ}^{Shunt} ) \qquad ( 20 )$$

$${( {P}_{ij}^{Bra} + Δ {P}_{ij}^{Bra} )}^{2} + {( {Q}_{ij}^{Bra} + Δ {Q}_{ij}^{Bra} )}^{2} \leq {( {S}_{ij}^{max} )}^{2} ( ( i , j ) ∈ {Φ}^{Bra} ) \qquad ( 21 )$$

$${\underline{ϕ}}_{i}^{V} \leq {ΔV}_{i} \leq {\overline{ϕ}}_{i}^{V} ( i ∈ {Φ}^{Gen} ) \qquad ( 22 )$$

$${\underline{ϕ}}_{i}^{Q} \leq Δ {Q}_{i} \leq {\overline{ϕ}}_{i}^{Q} ( i ∈ {Φ}^{Gen} ) \qquad ( 23 )$$

Where, Vᵢ is voltage magnitude at bus i.

$${V}_{i}^{max} and {V}_{i}^{min}$$

are maximum and minimum voltage magnitudes at bus i. Φ^{Bus} represent collections of all system buses. Qᵢ is reactive power injection at bus i.

$${Q}_{i}^{max} and {Q}_{i}^{min}$$

are upper and lower limits of Qᵢ at generation bus i. Φ^{Gen} is the subset of generations buses. Tᵢ is the transformer tap position of the ith OLTC, of which upper and lower limits marked

$${T}_{i}^{max} and {T}_{i}^{min} .$$

Φ^{Trans} indicates the set of OLTCs. Sᵢ is the number of shunt capacitors deployed at bus i, of which upper bound is

$${S}_{i}^{max} .$$

Φ^{Shunt} Shunt represents the set of system buses deployed with compensators.

$${P}_{ij}^{Bra} and {Q}_{ij}^{Bra}$$

are active and reactive power flow carried by branch (i, j).

$${S}_{ij}^{max}$$

represents power flow limit of branch (i, j). Φ^{Bra} represent collections of all system branches.

$${\underline{ϕ}}_{i}^{V} , {\overline{ϕ}}_{i}^{V}$$

are optimization step upper and lower limit for voltage magnitude at generation bus i.

$${\underline{ϕ}}_{i}^{G} , {\overline{ϕ}}_{i}^{G}$$

are optimization step upper and lower limit for reactive power injection at generation bus i.

Above is the expression of reactive power optimization model. Following materials provide calculation method of elements in submatrices shown in (15), and the linearization approach of (21).

As derivative of f^{P} and f^{Q} has been provided above, here we only give the derivative of branch power flow, including the derivative to voltage magnitudes and phase angles, which are demonstrated in (24)-(27):

$$\{ \begin{matrix}\frac{\partial {g}_{ij}^{P}}{\partial {V}_{i}} = - 2 {G}_{ij} {V}_{i} + {G}_{ij} {V}_{j} cos {θ}_{ij} + {B}_{ij} {V}_{j} sin {θ}_{ij} \\ \frac{\partial {g}_{ij}^{P}}{\partial {V}_{j}} = {G}_{ij} {V}_{i} cos {θ}_{ij} + {B}_{ij} {V}_{i} sin {θ}_{ij}\end{matrix} ( ( i , j ) ∈ {Φ}^{Bra} ) \qquad ( 24 )$$

$$\{ \begin{matrix}\frac{\partial {g}_{ij}^{Q}}{\partial {V}_{i}} = 2 {B}_{ij} {V}_{i} - {B}_{ij} {V}_{j} cos {θ}_{ij} + {G}_{ij} {V}_{j} sin {θ}_{ij} \\ \frac{\partial {g}_{ij}^{Q}}{\partial {V}_{j}} = - {B}_{ij} {V}_{i} cos {θ}_{ij} + {G}_{ij} {V}_{i} sin {θ}_{ij}\end{matrix} ( ( i , j ) ∈ {Φ}^{Bra} ) \qquad ( 25 )$$

$$\{ \begin{matrix}\frac{\partial {g}_{ij}^{P}}{\partial {θ}_{i}} = - {G}_{ij} {V}_{i} {V}_{j} sin {θ}_{ij} + {B}_{ij} {V}_{i} {V}_{j} cos {θ}_{ij} \\ \frac{\partial {g}_{ij}^{P}}{\partial {θ}_{j}} = {G}_{ij} {V}_{i} {V}_{j} sin {θ}_{ij} - {B}_{ij} {V}_{i} {V}_{j} cos {θ}_{ij}\end{matrix} ( ( i , j ) ∈ {Φ}^{Bra} ) \qquad ( 26 )$$

$$\{ \begin{matrix}\frac{\partial {g}_{ij}^{Q}}{\partial {θ}_{i}} = {B}_{ij} {V}_{i} {V}_{j} sin {θ}_{ij} + {G}_{ij} {V}_{i} {V}_{j} cos {θ}_{ij} \\ \frac{\partial {g}_{ij}^{Q}}{\partial {θ}_{j}} = - {B}_{ij} {V}_{i} {V}_{j} sin {θ}_{ij} - {G}_{ij} {V}_{i} {V}_{j} cos {θ}_{ij}\end{matrix} ( ( i , j ) ∈ {Φ}^{Bra} ) \qquad ( 27 )$$

Where,

$${g}_{ij}^{P} and {g}_{ij}^{Q}$$

represent equations for active power and reactive power of branch (i, j). Vᵢ is voltage magnitude at bus i. θᵢ symbolizes phase angel at bus i. θᵢⱼ is the phase angle between bus i and j. Gᵢᵢ and Bᵢᵢ are self-conductance and self-susceptance at bus i. Gᵢⱼ and Bᵢⱼ represent mutual conductance mutual susceptance between buses i and j. Φ^{Bra} represent collections of all system branches.

Derivative to reactive power generation can be acquired by differentiating active and reactive power equations to reactive power injections, as shown in (28)-(29):

$$\frac{\partial {f}_{i}^{P}}{\partial {Q}_{i}^{G}} = 0 ( i , j ∈ {Φ}^{Gen} ) \qquad ( 28 )$$

$$\frac{\partial {f}_{i}^{P}}{\partial {Q}_{i}^{G}} = \{ \begin{matrix}1 & ( i = j ; i , j ∈ {Φ}^{Gen} ) \\ 0 & ( else )\end{matrix} \qquad ( 29 )$$

Where,

$${f}_{i}^{P} and {f}_{i}^{Q}$$

represent active power and reactive power balance equations of bus i.

$${Q}_{j}^{G}$$

is reactive power injection at generation bus j. Φ^{Gen} is the subset of generations buses.

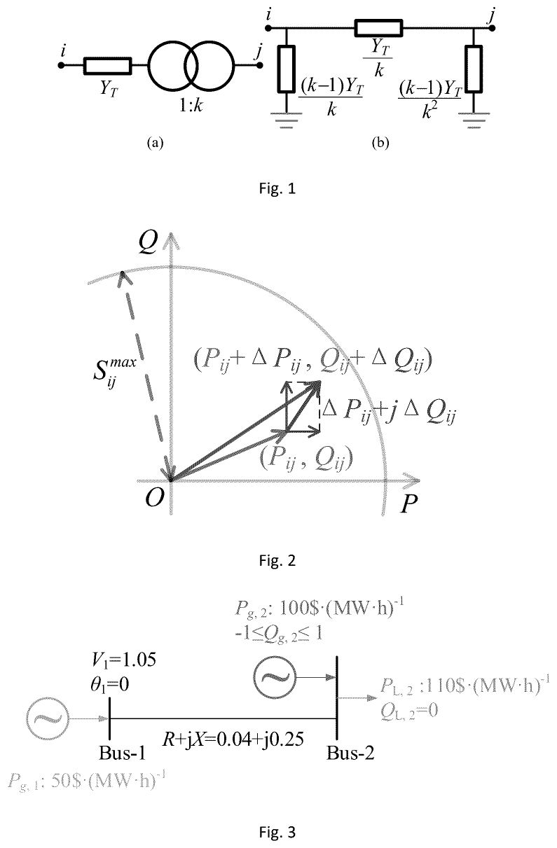

For the derivative to transformer taps, under a per-unit network, using the serial form of transformer reactance and ideal transformer, mathematical model of transformers is established in (a) of FIG. 1, whose equivalent circuit is shown in (b) of FIG. 1. In FIG. 1, k is non-standard ratio of the transformer. Y_{T} represents the transformer series admittance.

The relationship between non-standard ratio of the transformer k and tap position T is demonstrated in (30):

$$\begin{matrix}k = {k}_{0} ( 1 + {Tk}_{T} ) \\ ( {k}_{T} = 2.5 \% ; T ∈ \{ - 4 , - 3 , ⋯ , 3 , 4 \} )\end{matrix} \qquad ( 30 )$$

Where, k₀ is rated non-standard ratio of the transformer. k_{T} indicates the variation of transformer ratio corresponding to one tap position change.

Differentiating k to T, relationship between dk and dT is shown in (31), which is applied in transition between derivative to k and T for further calculation.

$$\frac{dk}{dT} = {k}_{T} {k}_{0} \qquad ( 31 )$$

As shown in FIG. 1, list the self and mutual admittance between bus i and j, as demonstrated in (32)-(34):

$$\begin{matrix}{G}_{ii} + {jB}_{ii} = \frac{( k - 1 )}{k} {Y}_{T} + \frac{{Y}_{T}}{k} = {Y}_{T} & ( {Y}_{T} = {G}_{T} + {jB}_{T} )\end{matrix} \qquad ( 32 )$$

$${G}_{jj} + {jB}_{jj} = \frac{( k - 1 )}{{k}^{2}} {Y}_{T} + \frac{{Y}_{T}}{k} = \frac{{Y}_{T}}{{k}^{2}} \qquad ( 33 )$$

$${G}_{ij} + {B}_{ij} = - \frac{{Y}_{T}}{k} \qquad ( 34 )$$

Differentiating (32)-(34) to T and plug in (31), we get:

$$\frac{\partial {G}_{ii}}{\partial T} = \frac{\partial {B}_{ii}}{\partial T} = 0 \qquad ( 35 )$$

$$\frac{\partial {G}_{ij}}{\partial T} + j \frac{\partial {B}_{ij}}{\partial T} = \frac{{k}_{0} {k}_{T}}{{k}^{2}} {G}_{T} + j \frac{{k}_{0} {k}_{T}}{{k}^{2}} {B}_{T} \qquad ( 36 )$$

$$\frac{\partial {G}_{jj}}{\partial T} + j \frac{\partial {B}_{jj}}{\partial T} = \frac{- 2 {k}_{0} {k}_{T}}{{k}^{3}} {G}_{T} + j \frac{- 2 {k}_{0} {k}_{T}}{{k}^{3}} {B}_{T} \qquad ( 37 )$$

Differentiating f^{P}, f^{Q}, g^{P} and g^{Q} to T and plug in (35)-(37), we get:

$$\{ \begin{matrix}\frac{\partial {f}_{i}^{P}}{\partial T} = - \frac{{k}_{0} {k}_{T}}{{k}^{2}} {V}_{i} {V}_{j} ( {G}_{T} cos {θ}_{ij} + {B}_{T} sin {θ}_{ij} ) \\ \frac{\partial {f}_{j}^{P}}{\partial T} = \frac{2 {k}_{0} {k}_{T}}{{k}^{3}} {G}_{T} {V}_{i}^{2} - \frac{{k}_{0} {k}_{T}}{{k}^{2}} {V}_{i} {V}_{j} ( {G}_{T} cos {θ}_{ij} - {B}_{T} sin {θ}_{ij} ) \\ \frac{\partial {f}_{i}^{Q}}{\partial T} = - \frac{{k}_{0} {k}_{T}}{{k}^{2}} {V}_{i} {V}_{j} ( {G}_{T} sin {θ}_{ij} - {B}_{T} cos {θ}_{ij} ) \\ \frac{\partial {f}_{j}^{Q}}{\partial T} = - \frac{2 {k}_{0} {k}_{T}}{{k}^{3}} {B}_{T} {V}_{i}^{2} + \frac{{k}_{0} {k}_{T}}{{k}^{2}} {V}_{i} {V}_{j} ( {G}_{T} sin {θ}_{ij} + {B}_{T} cos {θ}_{ij} )\end{matrix} ( i , j ∈ {Φ}^{B} ) \qquad ( 38 )$$

$$\{ \begin{matrix}\frac{\partial {g}_{ij}^{P}}{\partial T} = - \frac{{k}_{0} {k}_{T}}{{k}^{2}} {G}_{T} ( {V}_{i}^{2} - {V}_{i} {V}_{j} cos {θ}_{ij} ) + \frac{{k}_{0} {k}_{T}}{{k}^{2}} {B}_{T} {V}_{i} {V}_{j} sin {θ}_{ij} \\ \frac{\partial {g}_{ij}^{Q}}{\partial T} = - \frac{{k}_{0} {k}_{T}}{{k}^{2}} {B}_{T} ( {V}_{i}^{2} - {V}_{i} {V}_{j} cos {θ}_{ij} ) + \frac{{k}_{0} {k}_{T}}{{k}^{2}} {G}_{T} {V}_{i} {V}_{j} sin {θ}_{ij}\end{matrix} ( ( i , j ) ∈ {Φ}^{Bra} ) \qquad ( 39 )$$

Where, k and k₀ are actual and rated non-standard ratio of the transformer. k_{T} indicates the variation of transformer ratio corresponding to one tap position change. Gᵢᵢ and Bᵢᵢ are self-conductance and self-susceptance at bus i. Gᵢⱼ and Bᵢⱼ represent mutual conductance mutual susceptance between buses i and j. Y_{T} represents the transformer series admittance.

$${f}_{i}^{P} and {f}_{i}^{Q}$$

represent active power and reactive power balance equations of bus i.

$${g}_{ij}^{P} and {g}_{ij}^{Q}$$

represent equations for active power and reactive power of branch (i, j). Vᵢ is voltage magnitude at bus i. θᵢⱼ is the phase angle between bus i and j.

In a similar way with (38) and (39), derivative to shunt capacitors can be obtained by differentiating active and reactive power equations to S. We get:

$$\{ \begin{matrix}\frac{\partial {f}_{i}^{P}}{\partial {S}_{i}} = - \frac{\partial ( {V}_{i}^{2} ( {G}_{ii} cos {θ}_{ii} - {B}_{ii} sin {θ}_{ii} ) )}{\partial S} = 0 \\ \frac{\partial {f}_{i}^{Q}}{\partial {S}_{i}} = - \frac{\partial ( {V}_{i}^{2} ( {G}_{ii} sin {θ}_{ii} - {B}_{ii} cos {θ}_{ii} ) )}{\partial S} = {V}_{i}^{2} {B}_{s}\end{matrix} ( i ∈ {Φ}^{s} ) \qquad ( 40 )$$

Where,

$${f}_{i}^{P} and {f}_{i}^{Q}$$

represent active power and reactive power balance equations of bus i. Sᵢ is the number of shunt capacitors deployed at bus i. Gᵢᵢ and Bᵢᵢ are self-conductance and self-susceptance at bus i. θᵢⱼ is the phase angle between bus i and j. Vᵢ is voltage magnitude at bus i. B_{S} denotes compensator series susceptance.

iterative relationship of branch power flow.

Linearization method of branch power flow constraints, and the iterative relationship of is shown in FIG. 2. As the scale of

$$Δ {P}_{ij}^{B r a} and Δ {Q}_{ij}^{Bra}$$

is relatively small in a single iteration,

$$Δ {P}_{ij}^{Bra} and Δ {Q}_{ij}^{Bra}$$

can be decoupled, thus we obtain:

$$- {P}_{ij}^{Bra} - {P}_{ij}^{′} \leq Δ {P}_{ij}^{Bra} \leq - {P}_{ij}^{bra} + {P}_{ij}^{′} \qquad ( 41 )$$

$$( {P}_{ij}^{′} = \sqrt{{( {S}_{ij}^{max} )}^{2} - {( {Q}_{ij}^{Bra} )}^{2}} ( ( i , j ) ∈ {Φ}^{Bra} ) )$$

$$- {Q}_{ij}^{Bra} - {Q}_{ij}^{′} \leq Δ {Q}_{ij}^{Bra} \leq - {Q}_{ij}^{bra} + {Q}_{ij}^{′} \qquad ( 42 )$$

$$( {Q}_{ij}^{′} = \sqrt{{( {S}_{ij}^{max} )}^{2} - {( {P}_{ij}^{Bra} )}^{2}} ( ( i , j ) ∈ {Φ}^{Bra} ) )$$

Where,

$${P}_{ij}^{B r a} and {Q}_{ij}^{Bra}$$

are active and reactive power flow carried by branch (i, j).

$${S}_{ij}^{max}$$

represents power flow limit of branch (i, j). Φ^{Bra} represent collections of all system branches.

The regulation method of optimization step limit includes:

The reason of setting optimization step limit lines in that there exists error in the linearization of equality constraints, also the power flow equations. Relatively large optimization step limit can enlarge feasible region, but will cause relatively large nonlinearity error. As the object of reactive power optimization is to minimize unbalanced power of the system, the present disclosure defines nonlinearity error χ as the principle of step size control, as shown in (43).

$${χ}^{( k )} = {μ}^{( k )} - {μ}^{best} \qquad ( 43 )$$

Where, χ^{(k)} is the error index. μ^{(k)} symbolizes unbalanced power acquired form power flow calculation after k^{th} reactive power optimization. μ^{best} is the minimum unbalanced power ever recorded in history.

When μ^{(k)} breaks the best record μ^{best}, step size is enlarged and μ^{best} is updated. Otherwise, it is reduced as shown (44)-(47).

$${\underline{ϕ}}_{i}^{V ( k + 1 )} = \{ \begin{matrix}{η}_{1} {\underline{ϕ}}_{i}^{V ( k )} ( {χ}^{( k )} > 0 ) \\ max ( {η}_{2} {\underline{ϕ}}_{i}^{V ( k )} , {V}_{i}^{min} - {V}_{i} ) ( {χ}^{( k )} \leq 0 )\end{matrix} \qquad ( 44 )$$

$${\overline{ϕ}}_{i}^{V ( k + 1 )} = \{ \begin{matrix}{η}_{1} {\overline{ϕ}}_{i}^{V ( k )} ( {χ}^{( k )} > 0 ) \\ min ( {η}_{2} {\overline{ϕ}}_{i}^{V ( k )} , {V}_{i}^{max} - {V}_{i} ) ( {χ}^{( k )} \leq 0 )\end{matrix} \qquad ( 45 )$$

$${\underline{ϕ}}_{i}^{Q ( k + 1 )} = \{ \begin{matrix}{η}_{1} {\underline{ϕ}}_{i}^{Q ( k )} ( {χ}^{( k )} > 0 ) \\ max ( {η}_{2} {\underline{ϕ}}_{i}^{Q ( k )} , {Q}_{i}^{min} - {Q}_{i} ) ( {χ}^{( k )} \leq 0 )\end{matrix} \qquad ( 46 )$$

$${\overline{ϕ}}_{i}^{Q ( k + 1 )} = \{ \begin{matrix}{η}_{1} {\overline{ϕ}}_{i}^{Q ( k )} ( {χ}^{( k )} > 0 ) \\ min ( {η}_{2} {\overline{ϕ}}_{i}^{Q ( k )} , {Q}_{i}^{max} - {Q}_{i} ) ( {χ}^{( k )} \leq 0 )\end{matrix} \qquad ( 47 )$$

Where

$${\underline{ϕ}}_{i}^{V} , {\overline{ϕ}}_{i}^{V}$$

are optimization step upper and lower limit for voltage magnitude at generation bus i.

$${\underline{ϕ}}_{i}^{G} , {\overline{ϕ}}_{i}^{G}$$

are optimization step upper and lower limit for reactive power injection at generation bus i. k is the number of iterations and χ^{(k)} is the error index. η₁ and η₂ are step adjustment parameters that satisfy 0<η₁<1<η₂. Vᵢ is voltage magnitude at bus i.

$${V}_{i}^{max} and {V}_{i}^{min}$$

are maximum and minimum voltage magnitudes at bus i. Qᵢ is reactive power injection at bus i.

$${Q}_{i}^{max} and {Q}_{i}^{min}$$

are upper and lower limits of Qᵢ at generation bus i.

Solution of available transfer capability based on continuation power flow includes:

As shown in (3), λ=0 represents original load and generation status. Power flow equations, or (3), can be regarded as parameterized equation about λ, whose geometric meaning is a curve in the solution space shown in (48):

$$F ( Y ) = F ( X , λ ) = 0 ( Y = [ \begin{matrix}μ & θ & V & λ ] )\end{matrix} \qquad ( 48 )$$

To discover the limit of power flow transition, trace along with the curve according to continuation power flow, through repetitive predictor and corrector steps, enlarging λ, so as to get voltage stability limit.

Before continuation power flow calculation, power growth mode of load and generation should be given in advance.

To guarantee incremental active and reactive power balance in continuation power flow calculation process, sum of

$${K}_{i}^{P} and {K}_{i}^{Q}$$

should be 0 respectively, as demonstrated in (49):

$$K = {\begin{matrix}[ {K}_{1}^{P} & {K}_{2}^{P} & L & {K}_{NB}^{P} & {K}_{1}^{Q} & {K}_{2}^{Q} & L & {K}_{NB}^{Q} ]\end{matrix}}^{T} ( {\sum }_{i = 1}^{NB} {K}_{i}^{P} = 0 ; {\sum }_{i = 1}^{NB} {K}_{i}^{Q} = 0 ) \qquad ( 49 )$$

Where, μ is the level of system unbalance power. θ is the vector of voltage phase angles except for the slack bus. V is the vector of voltage magnitudes. λ represents power incremental parameter. Y symbolizes continuation power flow solution vector.

$${K}_{i}^{P} and {K}_{i}^{Q}$$

are active and reactive power increase coefficients for the bus i relative to λ. NB is the total bus count of the network.

Further preferably, predictor. Calculation method of predictor steps is below:

$${Y}^{pre} = {Y}^{base} + σ \frac{dY}{{‖ dY ‖}_{2}} \qquad ( 50 )$$

$$\{ \begin{matrix}{{J}_{CPF} [ dY ]}^{T} = [ \begin{matrix}0 \\ 1\end{matrix} ] \\ {J}_{CPF} = [ \begin{matrix}\begin{matrix}{J}_{PF} & K\end{matrix} \\ {e}_{c}\end{matrix} ]\end{matrix}$$

$$( {e}_{c} = [ \begin{matrix}0 & L & 0 & 1 & 0 & L & 0\end{matrix} ] ; c = \{ c ‖ {dy}_{c} \vert = {‖ dY ‖}_{∞} \} ) \qquad ( 51 )$$

Where, Y^{base} is original continuation power flow solution, and Y^{pre} represents the solution to be predicted. σ is step-size control coefficient. dY is tangent predictor vector, and ∥dY∥₂ is the second norm of dY. dY/∥dY∥₂ is the normalization of predictor step, thus o represents actual step size regardless the modulus of dY. J_{CPF} marks the Jacobian matrix for continuation power flow calculation. J_{PF} symbolizes the Jacobian matrix for power flow calculation. K is the vector consisting of

$${K}_{i}^{P} and {K}_{i}^{Q} .$$

e_{c} is a vector for which the cth element is 1 while others are 0.

Recognition of bifurcation: Bifurcation is a sign where power system reaches voltage stability limit as the increase of λ, including two criterions, saddle node bifurcation (SNB) and limit induced bifurcation (LIB).

Saddle node bifurcation (SNB) represents the situation where λ is unable to increase further, whose criterion is dλ<0.

Limit induced bifurcation (LIB) represents the situations where system reactive power reservation is exhausted, whose criterion is that there exists a bus whose VQ sensitivity is negative. If there exists at least one bus whose voltage magnitude declines along with the increase of reactive power injection, system voltage is unstable. Calculation method of minimum VQ sensitivity for each bus is listed in (52):

$${δ}^{min} = min \{ {δ}_{i} \vert δ = diag {( {J}_{CPF} )}^{- 1} , i ∈ {Φ}^{L} \} > 0 \qquad ( 52 )$$

Where, δᵢ is the VQ sensitivity of bus i. δ represents the vector of VQ sensitivity, which is also the diagonal elements of (J_{CPF})⁻¹. δ^{min} is the minimum VQ sensitivity of all buses. Φ^{L} is the subset of load buses.

Corrector: Corrector steps are as follows:

Due to the nonlinear feature of the curve, predicted solution is not on the curve F(Y), which requires local parameterization to get power flow solution as shown in (53).

$$G ( Y ) = \{ \begin{matrix}F ( Y ) = 0 \\ {y}_{c} - {y}_{c}^{pre} = 0\end{matrix} \qquad ( 53 )$$

Where, Y symbolizes continuation power flow solution vector. G is the equation set of continuation power flow. y_{c} is the prolonged factor and

$${y}_{c}^{pre}$$

is y_{c} obtained from predictor steps.

Solution of (53) is similar with power flow calculation, as shown in (54), whose convergence criterion is given in (55):

$$\{ \begin{matrix}G ( {Y}^{( s )} ) = ( {J}_{CPF} {\vert}_{Y = {Y}^{( s )}} ) {( Δ {Y}^{( s )} )}^{T} = {{J}_{CPF}^{( s )} ( Δ {Y}^{( s )} )}^{T} \\ {Y}^{( s + 1 )} = {Y}^{( s )} + Δ {Y}^{( s )}\end{matrix} \qquad ( 54 )$$

$${ε}^{CPF} = {‖ G ( Y ) ‖}_{∞} \qquad ( 55 )$$

Where, Y symbolizes continuation power flow solution vector. G is the equation set of continuation power flow. s and (s+1) represent the number of iterations. Y^{(s)} the value of Y in s^{th} iteration. J_{CPF} marks the Jacobian matrix for continuation power flow calculation. ε^{CPF} is the infinite norm of G(X).

Excessively large step size will cause longer distance between predicted solution and curve F(Y), increasing the number of iterations, while excessively small step size will increase unnecessary predictor-corrector steps, decreasing computation efficiency. To balance the increase speed of λ and predictor-corrector computation efficiency, it is necessary to regulate the continuation power flow step size σ.

The number of iterations of (54) indirectly indicates the distance between predicted solution and continuation power flow curve. Larger the number of iterations is, longer the distance is, representing stronger nonlinear feature of the curve, thus step size should be reduced, whereas should be enlarged. Accordingly, select the number of iterations in corrector steps as the reference of adjusting step size σ, as shown in (56).

$$σ = \{ \begin{matrix}{β}_{1} σ & ( sc > ξ ) \\ {β}_{2} σ & ( sc \leq ξ )\end{matrix} \qquad ( 56 )$$

Where, sc is the number of iterations. ξ is a threshold concerning enlarging of decreasing step size. β₁ and β₂ are constants that satisfy 0<β₁<1<β₂.

To validate the effectiveness of proposed model, based on a simple 2 bus test system and its operational parameters, available transfer capability is calculated accordingly, thus verifying the performance of the model.

Topological structure and parameters of the system are shown in FIG. 3. Upper and lower limits of reactive power injection and voltage magnitude of the two buses are shown in Table 1.

TABLE 1

| Variable | Lower limit | Upper limit |
|---|---|---|
| Q_{g, 1} | −1.00 | 1.00 |
| Q_{g, 2} | −1.00 | 1.00 |
| V₁ | 0.95 | 1.05 |
| V₂ | 0.95 | 1.05 |

Configuration of major calculation parameters of the system is shown in Table 2.

TABLE 2

| K₁^{P} | K₂^{P} | α₁ | ε^{min} | ε^{max} | σ^{min} | ξ | β₁ | β₂ | η₁ | η₂ |
|---|---|---|---|---|---|---|---|---|---|---|
| 1 | −1 | 1 | 10⁻⁶ | 10⁵ | 10⁻⁴ | 2 | 0.5 | 2 | 0.5 | 2 |

Calculation process and solution analysis of available transfer capability is below:

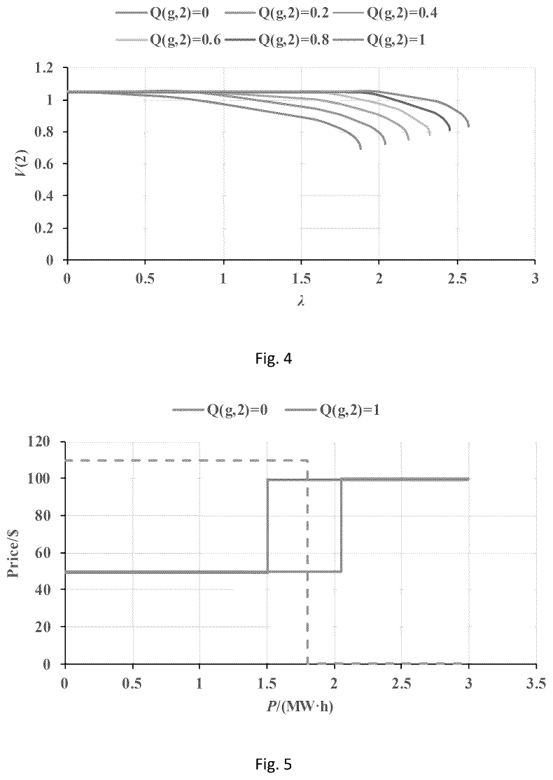

Neglecting reactive power optimization, continuation power flow calculation results is λ=1.88, while λ=2.57 if reactive power optimization is considered. In this invention, the value of λ obtained from continuation power flow calculation is multiplied by 0.8 as P_{ATC}, so available transfer capability from bus 1 to 2 is 1.88×0.8=1.504 p.u., or 150.4 MW, if reactive power support is not considered, and 2.57×0.8=2.056 p.u., or 205.6 MW, if reactive power support is considered. FIG. 4 shows the voltage magnitude of each bus in the calculation process under different values of reactive power generation at bus 2. As can be observed, reactive power support has the effect of reducing transmission loss and improving voltage magnitude, and is able to indicate ATC of the network more precisely.

Using the ATC calculation result, power transaction results, or the electricity price and traded amount for generators and consumers are obtained. In FIG. 3, generator at bus 1 delivers electric power to consumers at bus 2 restricted by the ATC of the transmission line, and there also exists a local generator at bus 2. We suppose that, the bid price of generator 1 is 50$·(MW·h)⁻¹, and the bid price of generator at bus 2 is 100$·(MW·h)⁻¹. Power demand of consumers at bus 2 is 180 MW·h, whose bid price is 110$·(MW·h)⁻¹.

FIG. 5 demonstrates the demand curve in dotted line, and the supply curves in full lines. Two supply curves marked green and blue are decided under the restriction of ATC with or without reactive power support, respectively. If power demand is lower than ATC, expensive electric power generated at bus 2 will not be bought, so the electricity price is 50$·(MW·h)⁻¹. If demand is higher than ATC, consumers cannot buy electric power only from remote generator at bus 1, so the electricity price is 100$·(MW·h)⁻¹.

When reactive power support is not considered, supply curve intersects with the demand curve at (180, 100). According to the restriction of ATC, output of generator at bus 1 is 150.4 MW·h, whose income is 150.4×100=15040$. Output of generator at bus 2 is 29.6 MW·h, whose income is 29.6×100=2960$. Total cost of consumers at bus 2 is 180×100=18000$. In this case, the total social welfare is: F=110×180−50×150.4−100×29.6=9320$.

In contrast, if reactive power support is considered, supply curve intersects with the demand curve at (180,50). Since traded amount is smaller than ATC, output of generator at bus 1 is 180 MW·h, whose income is 180×50=9000$. Expensive electric power at bus 2 is not needed to satisfy the need, so the electricity price is 50$·(MW·h)⁻¹ Instead of 100. Cost of consumers at bus 2 is 180×50=9000$. In this scenario, total social welfare is: F=110×180−50×180=10800$.

Calculation results above under different ATC values indicate that, reactive power support has great impact on power transaction result and the economic benefits. Optimized reactive power support can effectively alleviate the problem of increasing electricity price caused by network congestion.

To conclude, the present disclosure considers optimized adjustment of power system regulative resources. Linear optimization model of regulative resources like shunt capacitors, transformer taps and voltage and reactive power of generators are deduced. Available transfer capability calculation method considering reactive power support is established, and predictor-corrector algorithm is designed to solve the problem that Jacobian matrix becomes singular near steady state voltage stability limit. Case study result of a 2 bus system shows that proposed model enables the system to have reduced transmission loss and improved voltage magnitude, and indicates available transfer capability of the network more precisely.

### Example 3

A computer device, comprising a memory and a processor, wherein the memory stores a computer program, and the processor executes the computer program to implement the steps of available transfer capability calculation method considering reactive power support as mentioned in Example 1 or 2.

### Example 4

A computer readable storage medium, wherein the medium stores a computer program, and the program is executed by processor to implement the steps of available transfer capability calculation method considering reactive power support as mentioned in Example 1 or 2.

### Example 5

A solving system of available transfer capability calculation considering reactive power support includes:

Power flow modeling and solving module, configured as: modeling and solving power flow equations:

Establishment of reactive power optimization modeling module, configured as: establish reactive power optimization model based on mixed integer linear programming, including: power system voltage regulation consists of adjusting reactive power injection

of generators, changing transformer taps and switching capacitors. The object of reactive power optimization is to get best voltage support by adjusting three types of control variables: adjusting reactive power injection of generators, changing transformer taps and switching capacitors.

Available transfer capability calculation module, configured as: solving available transfer capability based on continuation power flow.

What is claimed is:

1. An available transfer capability calculation method considering reactive power support, comprising a non-transitory computer readable medium operable on a computer with memory for the available transfer capability calculation method, and comprising program instructions for executing the following steps of:
modeling and solving power flow equations:
establishing reactive power optimization model based on mixed integer linear programming that comprises: power system voltage regulation consisting of adjusting reactive power injection of generators, changing transformer taps and switching capacitors; the object of reactive power optimization is to get best voltage support by adjusting three types of control variables: adjusting reactive power injection of generators, changing transformer taps and switching capacitors;
solving available transfer capability by continuation power flow;
modeling and solving power flow equations comprises:
acquiring improved power flow formulations, as shown below:
$$\{ \begin{matrix}{f}^{P} = \{ {P}_{i} - {\sum }_{j = 1}^{NB} {V}_{i} {V}_{j} ( {G}_{ij} cos {θ}_{ij} + {B}_{ij} sin {θ}_{ij} ) = 0 ( i ∈ {Φ}^{Bus} ) \\ {f}^{Q} = \{ {Q}_{i} - {\sum }_{j = 1}^{NB} {V}_{i} {V}_{j} ( {G}_{ij} sin {θ}_{ij} + {B}_{ij} cos {θ}_{ij} ) = 0 ( i ∈ {Φ}^{Bus} )\end{matrix} \qquad ( 1 )$$
$$\{ \begin{matrix}{g}^{P} = \{ \begin{matrix}{P}_{ij}^{Bra} - {G}_{ij} ( {V}_{i}^{2} - {V}_{i} {V}_{j} cos {θ}_{ij} ) + {B}_{ij} {V}_{i} {V}_{j} sin {θ}_{ij} = 0 \\ ( ( i , j ) ∈ {Φ}^{Bra} )\end{matrix} \\ {g}^{Q} = \{ \begin{matrix}{Q}_{ij}^{Bra} - {B}_{ij} ( {V}_{i}^{2} - {V}_{i} {V}_{j} cos {θ}_{ij} ) + {G}_{ij} {V}_{i} {V}_{j} sin {θ}_{ij} = 0 \\ ( ( i , j ) ∈ {Φ}^{Bra} )\end{matrix}\end{matrix} \qquad ( 2 )$$
$$\{ \begin{matrix}{P}_{i} = {P}_{i 0} + {μα}_{i} + λ {K}_{i}^{P} \\ {Q}_{i} = {Q}_{i 0} + λ {K}_{i}^{Q}\end{matrix} \qquad ( 3 )$$
wherein, f^{P} and f^{Q} represent active power and reactive power balance equations; g^{P} and g^{Q} represent equations for active power and reactive power of branches; Pᵢ and Qᵢ are active and reactive power injections at bus i, while Pᵢ₀ and Qᵢ₀ are Pᵢ and Qᵢ at initial PF state;
$${P}_{ij}^{Bra} and {Q}_{ij}^{Bra}$$
are active and reactive power flow carried by branch (i, j); Vᵢ is voltage magnitude at bus i; μ is the level of system unbalance power caused by power loss; αᵢ is AGC participating coefficient for generation bus i to handle the unbalance power; θᵢⱼ is the phase angle between complex bus voltages Vᵢ and Vⱼ; NB is the total bus count of the network; Gᵢᵢ and Bᵢᵢ are self-conductance and self-susceptance at bus i; Gᵢⱼ and Bᵢⱼ represent mutual conductance mutual susceptance between buses i and j; Φ^{Bus} represent collections of all system buses; Φ^{Bra} represent collections of all system branches; λ represents power incremental parameter, while
$${K}_{i}^{P} and {K}_{i}^{Q}$$
are active and reactive power increase coefficients for the bus i relative to λ;
an Auto Generation Control (AGC) participating coefficients are generally specified as constants which can be expressed as relation (4):
$$\begin{matrix}A = {[ \begin{matrix}{α}_{1} & {α}_{2} & L & {α}_{n}\end{matrix} ]}^{T} & ( {\sum }_{i = 1}^{n} {α}_{i} = 1 ; {α}_{i} \geq 0 )\end{matrix} \qquad ( 4 )$$
wherein, A is a vector of unbalanced power proportion;
compact from of equation (1) is expressed by:
$$\begin{matrix}F ( X ) = 0 & ( X = [ μ , θ , V ] )\end{matrix} \qquad ( 5 )$$
wherein, θ is the vector of voltage phase angles except for a slack bus; V is the vector of voltage magnitudes;
equation (5) is a nonlinear equation set, which can be solved by iterative algorithms; establishing newton iterative relations shown in (6),
$$\{ \begin{matrix}F ( {X}^{( s )} ) = ( \frac{\partial F ( X )}{\partial X} {\vert}_{X = {X}^{( s )}} ) {( Δ {X}^{( s )} )}^{T} = {{J}_{PF}^{( s )} ( Δ {X}^{( s )} )}^{T} \\ {X}^{( s + 1 )} = {X}^{( s )} - Δ {X}^{( s )}\end{matrix} \qquad ( 6 )$$
wherein, s and (s+1) represent the number of iterations, X^{(s)} the value of X in s^{th} iteration, the structure of Jacobian matrix
$${J}_{PF}^{( s )}$$
in (6) is elaborated as shown in (7),
$${J}_{PF}^{( s )} = ( \begin{matrix}A & \frac{\partial {f}^{P}}{\partial θ} & \frac{\partial {f}^{P}}{\partial V} \\ 0 & \frac{\partial {f}^{Q}}{\partial θ} & \frac{\partial {f}^{Q}}{\partial V}\end{matrix} ) {\vert}_{X = {X}^{( s )}} \qquad ( 7 )$$
derivative of active power equations to unbalanced power is A, derivative of active and reactive power equations to phase angles and voltage magnitudes are shown in (8)-(11);
$$\frac{\partial {f}_{i}^{P}}{\partial {θ}_{j}} = \{ \begin{matrix}{V}_{i}^{2} {B}_{ii} + {Q}_{i} & ( i = j ) \\ - {V}_{i} {V}_{j} ( {G}_{ij} sin {θ}_{ij} - {B}_{ij} cos {θ}_{ij} ) & ( else )\end{matrix} \qquad ( 8 )$$
$$\frac{\partial {f}_{i}^{P}}{\partial {V}_{j}} = \{ \begin{matrix}- {V}_{i}^{2} {G}_{ii} - {P}_{i} & ( i = j ) \\ - {V}_{i} {V}_{j} ( {G}_{ij} cos {θ}_{ij} + {B}_{ij} sin {θ}_{ij} ) & ( else )\end{matrix} \qquad ( 9 )$$
$$\frac{\partial {f}_{i}^{Q}}{\partial {θ}_{j}} = \{ \begin{matrix}{V}_{i}^{2} {G}_{ii} - {P}_{i} & ( i = j ) \\ {V}_{i} {V}_{j} ( {G}_{ij} cos {θ}_{ij} + {B}_{ij} sin {θ}_{ij} ) & ( else )\end{matrix} \qquad ( 10 )$$
$$\frac{\partial {f}_{i}^{Q}}{\partial {V}_{j}} = \{ \begin{matrix}{V}_{i}^{2} {B}_{ii} - {Q}_{i} & ( i = j ) \\ - {V}_{i} {V}_{j} ( {G}_{ij} sin {θ}_{ij} - {B}_{ij} cos {θ}_{ij} ) & ( else )\end{matrix} \qquad ( 11 )$$
wherein,
$${f}_{i}^{P} and {f}_{i}^{Q}$$
represent active power and reactive power balance equations of bus I, Pᵢ and Qᵢ are active and reactive power injections at bus I, Vᵢ is voltage magnitude at bus i; θᵢ
symbolizes phase angel at bus I, θᵢⱼ is the phase angle between bus i and j, Gᵢᵢ and Bᵢᵢ are self-conductance and self-susceptance at bus I, Gᵢⱼ and Bᵢⱼ represent mutual conductance mutual susceptance between buses i and j;
convergence principle of Newton method is elaborated in (12),
$${ε}^{PF} = {‖ F ( X ) ‖}_{∞} \qquad ( 12 )$$
considering the infinite norm of F(X), ε^{PF}, when ε^{PF} is less than a minimum positive (ε^{PF}<ε^{min}), the Newton iterations converge; moreover, divergence takes place if ε^{PF} exceeds an allowable level (ε^{PF}>ε^{max}), ε^{min} and ε^{max} are parameters for judging convergence and divergence of Newton method;
determining demands of the consumers for electric power; and
controlling output of the electric power of generators to meet demands of the consumers by optimizing adjustment of shunt capacitors, transformer taps, and enabling efficient and reliable movement of electrical energy.

2. The method according to claim 1, wherein the method establishes reactive power optimization model based on mixed integer linear programming:
objective function of reactive power optimization model is minimizing active power flow, or reducing unbalanced power Δμ, as shown in (13),
$$Min Δ μ \qquad ( 13 )$$
equality constraints of reactive power optimization are equation (1) and (2), which is a nonlinear equation set; substitute nonlinear equality constraints with linear ones, which are demonstrated in (14)-(16)
$${[ {J}_{OPF} {\vert}_{X = {X}^{( sc )}} ] [ Δ Z ]}^{T} = 0 \qquad ( 14 )$$
$${J}_{OPF} = [ \begin{matrix}A & \frac{\partial {f}^{P}}{\partial θ} & \frac{\partial {f}^{P}}{\partial V} \vert & \frac{\partial {f}^{P}}{\partial {Q}^{G}} & \frac{\partial {f}^{P}}{\partial T} & \frac{\partial {f}^{P}}{\partial S} \vert & 0 & 0 \\ 0 & \frac{\partial {f}^{Q}}{\partial θ} & \frac{\partial {f}^{Q}}{\partial V} \vert & \frac{\partial {f}^{Q}}{\partial {Q}^{G}} & \frac{\partial {f}^{Q}}{\partial T} & \frac{\partial {f}^{Q}}{\partial S} \vert & 0 & 0 \\ 0 & \frac{\partial {g}^{P}}{\partial θ} & \frac{\partial {g}^{P}}{\partial V} \vert & 0 & \frac{\partial {g}^{P}}{\partial T} & 0 \vert & E & 0 \\ 0 & \frac{\partial {g}^{Q}}{\partial θ} & \frac{\partial {g}^{Q}}{\partial V} \vert & 0 & \frac{\partial {g}^{Q}}{\partial T} & 0 \vert & 0 & E\end{matrix} ] \qquad ( 15 )$$
$$Δ Z = [ \begin{matrix}Δμ & Δθ & Δ V \vert & Δ {Q}^{G} & Δ T & Δ S \vert & Δ {P}^{Bra} & Δ {Q}^{Bra}\end{matrix} ] \qquad ( 16 )$$
wherein, Z denotes the vector of all the power flow state and control variables, T is the vector of the transformer tap position for all the on-load tap changers (OLTC), Q^{G} indicates reactive power injections at generation buses, P^{Bra} and Q^{Bra} represent the set of
$${P}_{ji}^{Bra} and {Q}_{ij}^{Bra} ,$$
E represents unit matrix;
the relations in (17)-(23) show the inequality constraints for reactive power optimization:
$$\begin{matrix}{V}_{i} - {V}_{i}^{min} \leq Δ {V}_{i} \leq {V}_{i} - {V}_{i}^{max} & ( i ∈ {Φ}^{Bus} )\end{matrix} \qquad ( 17 )$$
$$\begin{matrix}{Q}_{i}^{min} - {Q}_{i} \leq Δ {Q}_{i} \leq {Q}_{i}^{max} - {Q}_{i} & ( i ∈ {Φ}^{Gen} )\end{matrix} \qquad ( 18 )$$
$$\begin{matrix}{T}_{i}^{min} - {T}_{i} \leq Δ {T}_{i} \leq {T}_{i}^{max} - {T}_{i} & ( i ∈ {Φ}^{Trans} )\end{matrix} \qquad ( 19 )$$
$$\begin{matrix}max ( 0 - {S}_{i} , - 1 ) \leq Δ {S}_{i} \leq min ( {S}_{i}^{max} - {S}_{i} , 1 ) & ( i ∈ {Φ}^{Shunt} )\end{matrix} \qquad ( 20 )$$
$$\begin{matrix}{( {P}_{ij}^{Bra} + Δ {P}_{ij}^{Bra} )}^{2} + {( {Q}_{ij}^{Bra} + Δ {Q}_{ij}^{Bra} )}^{2} \leq {( {S}_{ij}^{max} )}^{2} & ( ( i , j ) ∈ {Φ}^{Bra} )\end{matrix} \qquad ( 21 )$$
$$\begin{matrix}\underline{{ϕ}_{i}^{V}} \leq Δ {V}_{1} \leq {\overline{{ϕ}_{i}}}^{V} & ( i ∈ {Φ}^{Gen} )\end{matrix} \qquad ( 22 )$$
$$\begin{matrix}\underline{{ϕ}_{i}^{Q}} \leq Δ {Q}_{i} \leq {\overline{{ϕ}_{i}}}^{Q} & ( i ∈ {Φ}^{Gen} )\end{matrix} \qquad ( 23 )$$
wherein, Vᵢ is voltage magnitude at bus I,
$${V}_{i}^{max} and {V}_{i}^{min}$$
are maximum and minimum voltage magnitudes at bus I, Φ^{Bus} represent collections of all system buses, Qᵢ is reactive power injection at bus I,
$${Q}_{i}^{max} and {Q}_{i}^{min}$$
are upper and lower limits of Qᵢ at generation bus I, Φ^{Gen} is the subset of generations buses; Tᵢ is the transformer tap position of the ith OLTC, of which upper and lower limits marked
$${T}_{i}^{max} and {T}_{i}^{min} ;$$
Φ^{Trans} indicates the set of OLTCs; Sᵢ is the number of shunt capacitors deployed at bus i, of which upper bound is
$${S}_{i}^{max} ;$$
Φ^{Shunt} represents the set of system buses deployed with compensators;
$${P}_{ij}^{Bra} and {Q}_{ij}^{Bra}$$
are active and reactive power flow carried by branch (i, j);
$${S}_{ij}^{max}$$
represents power flow limit of branch (i, j); Φ^{Bra} represent collections of all system branches;
$${\underline{{ϕ}_{i}}}^{V} , {\overline{{ϕ}_{i}}}^{V}$$
are optimization step upper and lower limit for voltage magnitude at generation bus I;
$${\underline{{ϕ}_{i}}}^{G} , {\overline{{ϕ}_{i}}}^{G}$$
are optimization step upper and lower limit for reactive power injection at generation bus i.

3. The method according to claim 2, wherein derivative of branch power flow to voltage magnitudes and phase angles are demonstrated in (24)-(27):
$$\{ \begin{matrix}\frac{\partial {g}_{ij}^{P}}{\partial {V}_{i}} = - 2 {G}_{ij} {V}_{i} + {G}_{ij} {V}_{j} cos {θ}_{ij} + {B}_{ij} {V}_{j} sin {θ}_{ij} \\ \frac{\partial {g}_{ij}^{P}}{\partial {V}_{j}} = {G}_{ij} {V}_{i} cos {θ}_{ij} + {B}_{ij} {V}_{i} sin {θ}_{ij}\end{matrix} ( ( i , j ) ∈ {Φ}^{Bra} ) \qquad ( 24 )$$
$$\{ \begin{matrix}\frac{\partial {g}_{ij}^{Q}}{\partial {V}_{i}} = - 2 {B}_{ij} {V}_{i} - {B}_{ij} {V}_{j} cos {θ}_{ij} + {G}_{ij} {V}_{j} sin {θ}_{ij} \\ \frac{\partial {g}_{ij}^{Q}}{\partial {V}_{j}} = - {B}_{ij} {V}_{i} cos {θ}_{ij} + {G}_{ij} {V}_{i} sin {θ}_{ij}\end{matrix} ( ( i , j ) ∈ {Φ}^{Bra} ) \qquad ( 25 )$$
$$\{ \begin{matrix}\frac{\partial {g}_{ij}^{P}}{\partial {θ}_{i}} = - {G}_{ij} {V}_{i} {V}_{j} sin {θ}_{ij} + {B}_{ij} {V}_{i} {V}_{j} cos {θ}_{ij} \\ \frac{\partial {g}_{ij}^{P}}{\partial {θ}_{j}} = {G}_{ij} {V}_{i} {V}_{j} sin {θ}_{ij} - {B}_{ij} {V}_{i} {V}_{j} cos {θ}_{ij}\end{matrix} ( ( i , j ) ∈ {Φ}^{Bra} ) \qquad ( 26 )$$
$$\{ \begin{matrix}\frac{\partial {g}_{ij}^{Q}}{\partial {θ}_{i}} = {B}_{ij} {V}_{i} {V}_{j} sin {θ}_{ij} + {G}_{ij} {V}_{i} {V}_{j} cos {θ}_{ij} \\ \frac{\partial {g}_{ij}^{Q}}{\partial {θ}_{j}} = - {B}_{ij} {V}_{i} {V}_{j} sin {θ}_{ij} - {G}_{ij} {V}_{i} {V}_{j} cos {θ}_{ij}\end{matrix} ( ( i , j ) ∈ {Φ}^{Bra} ) \qquad ( 27 )$$
wherein,
$${g}_{ij}^{P} and {g}_{ij}^{Q}$$
represent equations tor active power and reactive power of branch (i, j); Vᵢ is voltage magnitude at bus I, θᵢ symbolizes phase angel at bus I, θᵢⱼ is the phase angle between bus i and j, Gᵢᵢ and Bᵢᵢ are self-conductance and self-susceptance at bus I, Gᵢⱼ and Bᵢⱼ represent mutual conductance mutual susceptance between buses i and j, Φ^{Bra} represent collections of all system branches.

4. The method according to claim 2, wherein derivative to reactive power generation is acquired by differentiating active and reactive power equations to reactive power injections, as shown in (28)-(29):
$$\frac{\partial {f}_{i}^{P}}{\partial {Q}_{j}^{G}} = 0 ( i , j ∈ {Φ}^{Gen} ) \qquad ( 28 )$$
$$\frac{\partial {f}_{i}^{Q}}{\partial {Q}_{j}^{G}} = \{ \begin{matrix}1 & ( i = j ; j ∈ {Φ}^{Gen} \\ 0 & ( else )\end{matrix} \qquad ( 29 )$$
wherein,
$${f}_{j}^{P} and {f}_{i}^{Q}$$
represent active power and reactive power balance equations of bus I,
$${Q}_{j}^{G}$$
is reactive power injection at generation bus j, Φ^{Gen} is the subset of generations buses;
derivative to transformer taps, also the relationship between non-standard ratio of the transformer k and tap position T, is demonstrated in (30):
$$k = {k}_{0} ( 1 + {Tk}_{T} ) \\ ( {k}_{T} = 2.5 \% ; T ∈ \{ - 4 , - 3 , … , 3 , 4 \} ) \qquad ( 30 )$$
wherein, k₀ is rated non-standard ratio of the transformer, k_{T} indicates the variation of transformer ratio corresponding to one tap position change;
differentiating k to T, relationship between dk and dT is shown in (31), which is applied in transition between derivative to k and T for further calculation;
$$\frac{dk}{dT} = {k}_{T} {k}_{0} \qquad ( 31 )$$
listing the self and mutual admittance between bus i and j, as demonstrated in (32)-(34):
$${G}_{ii} + {jB}_{ii} = \frac{( k - 1 )}{k} {Y}_{T} + \frac{{Y}_{T}}{k} = {Y}_{T} ( {Y}_{T} = {G}_{T} + {jB}_{T} ) \qquad ( 32 )$$
$${G}_{jj} + {jB}_{jj} = \frac{( k - 1 )}{{k}^{2}} {Y}_{T} + \frac{{Y}_{T}}{k} = \frac{{Y}_{T}}{{k}^{2}} \qquad ( 33 )$$
$${G}_{ij} + {jB}_{ij} = - \frac{{Y}_{T}}{k} \qquad ( 34 )$$
differentiating (32)-(34) to T and plug in (31), we get:
$$\frac{\partial {G}_{ii}}{\partial T} = \frac{\partial {B}_{ii}}{\partial T} = 0 \qquad ( 35 )$$
$$\frac{\partial {G}_{ij}}{\partial T} + j \frac{\partial {B}_{ij}}{\partial T} = \frac{{k}_{0} {k}_{T}}{{k}^{2}} {G}_{T} + j \frac{{k}_{0} {k}_{T}}{{k}^{2}} {B}_{T} \qquad ( 36 )$$
$$\frac{\partial {G}_{jj}}{\partial T} + j \frac{\partial {B}_{jj}}{\partial T} = \frac{- 2 {k}_{0} {k}_{T}}{{k}^{3}} {G}_{T} + j \frac{- 2 {k}_{0} {k}_{T}}{{k}^{3}} {B}_{T} \qquad ( 37 )$$
differentiating f^{P}, f^{Q}, g^{P} and g^{Q} to T and plug in (35)-(37), we get:
$$\{ \begin{matrix}\frac{\partial {f}_{i}^{P}}{\partial T} = - \frac{{k}_{0} {k}_{T}}{{k}^{2}} {V}_{i} {V}_{j} ( {G}_{T} cos {θ}_{ij} + {B}_{T} sin {θ}_{ij} ) \\ \frac{\partial {f}_{j}^{P}}{\partial T} = \frac{2 {k}_{0} {k}_{T}}{{k}^{3}} {G}_{T} {V}_{j}^{2} - \frac{{k}_{0} {k}_{T}}{{k}^{2}} {V}_{i} {V}_{j} ( {G}_{T} cos {θ}_{ij} - {B}_{T} sin {θ}_{ij} ) \\ \frac{\partial {f}_{i}^{Q}}{\partial T} = \frac{{k}_{0} {k}_{T}}{{k}^{2}} {V}_{i} {V}_{j} ( {G}_{T} sin {θ}_{ij} - {B}_{T} cos {θ}_{ij} ) \\ \frac{\partial {f}_{j}^{Q}}{\partial T} = \frac{2 {k}_{0} {k}_{T}}{{k}^{3}} {B}_{T} {V}_{j}^{2} + \frac{{k}_{0} {k}_{T}}{{k}^{2}} {V}_{i} {V}_{j} ( {G}_{T} sin {θ}_{ij} + {B}_{T} cos {θ}_{ij} )\end{matrix} ( i , j ∈ {Φ}^{B} ) \qquad ( 38 )$$
$$\{ \begin{matrix}\frac{\partial {g}_{ij}^{P}}{\partial T} = - \frac{{k}_{0} {k}_{T}}{{k}^{2}} {G}_{T} ( {V}_{i}^{2} - {V}_{i} {V}_{j} cos {θ}_{j} ) + \\ \frac{{k}_{0} {k}_{T}}{{k}^{2}} {B}_{T} {V}_{i} {V}_{j} sin {θ}_{ij} \\ \frac{\partial {g}_{ij}^{Q}}{\partial T} = \frac{{k}_{0} {k}_{T}}{{k}^{2}} {B}_{T} ( {V}_{i}^{2} - {V}_{i} {V}_{j} cos {θ}_{ij} ) + \\ \frac{{k}_{0} {k}_{T}}{{k}^{2}} {G}_{T} {V}_{i} {V}_{j} sin {θ}_{ij}\end{matrix} ( ( i , j ) ∈ {Φ}^{Bra} ) \qquad ( 39 )$$
wherein, k and k₀ are actual and rated non-standard ratio of the transformer; k_{T} indicates the variation of transformer ratio corresponding to one tap position change; Gᵢᵢ and Bᵢᵢ are self-conductance and self-susceptance at bus I; Gᵢⱼ and Bᵢⱼ represent mutual conductance mutual susceptance between buses i and j; Y_{T} represents the transformer series admittance;
$${f}_{i}^{P} and {f}_{i}^{Q}$$
represent active power and reactive power balance equations of bus I;
$${g}_{ij}^{P} and {g}_{ij}^{Q}$$
represent equations for active power and reactive power of branch (i, j); Vᵢ is voltage magnitude at bus I; θᵢⱼ is the phase angle between bus i and j;
derivative to shunt capacitors can be obtained by differentiating active and reactive power equations to S, we get:
$$\{ \begin{matrix}\frac{\partial {f}_{i}^{P}}{\partial {S}_{i}} = \frac{\partial ( {V}_{i}^{2} ( {G}_{ii} cos {θ}_{ii} + {B}_{ii} sin {θ}_{ii} ) )}{\partial S} = 0 \\ \frac{\partial {f}_{i}^{Q}}{\partial {S}_{i}} = \frac{\partial ( {V}_{i}^{2} ( {G}_{ii} sin {θ}_{ii} - {B}_{ii} cos {θ}_{ii} ) )}{\partial S} = {V}_{i}^{2} {B}_{S}\end{matrix} ( i ∈ {Φ}^{S} ) \qquad ( 40 )$$
wherein,
$${f}_{i}^{P} and {f}_{i}^{Q}$$
represent active power and reactive power balance equations of bus I; Sᵢ is the number of shunt capacitors deployed at bus I; Gᵢᵢ and Bᵢᵢ are self-conductance and self-susceptance at bus I; θᵢⱼ is the phase angle between bus i and j; Vᵢ is voltage magnitude at bus I; B_{S} denotes compensator series susceptance;
linearization method of branch power flow constraints can be obtained by decoupling
$$Δ {P}_{ij}^{Bra} and Δ {Q}_{ij}^{Bra} :$$
$$- {P}_{t j}^{Bra} - {P}_{ij}^{′} \leq Δ {P}_{ij}^{Bra} \leq - {P}_{ij}^{Bra} + {P}_{ij}^{′} \qquad ( 41 )$$
$$( {P}_{ij}^{′} = \sqrt{{( {S}_{ij}^{max} )}^{2} - {( {Q}_{ij}^{Bra} )}^{2}} ( ( i , j ) ∈ {Φ}^{Bra} ) )$$
$$- {Q}_{t j}^{Bra} - {Q}_{ij}^{′} \leq Δ {Q}_{ij}^{Bra} \leq - {Q}_{ij}^{Bra} + {Q}_{ij}^{′} \qquad ( 42 )$$
$$( {Q}_{ij}^{′} = \sqrt{{( {S}_{ij}^{max} )}^{2} - {( {P}_{ij}^{Bra} )}^{2}} ( ( i , j ) ∈ {Φ}^{Bra} ) )$$
wherein
$${P}_{ij}^{B r a} and {Q}_{ij}^{B r a}$$
are active and reactive power flow carried by branch (i, j),
$${S}_{ij}^{max}$$
represents power flow limit of branch (i, j), Φ^{Bra} represent collections of all system branches.

5. The method according to claim 2, wherein the method comprises the regulation method of optimization step limit:
define nonlinearity error χ as the principle of step size control, as shown in (43);
$${χ}^{( k )} = {μ}^{( k )} - {μ}^{best} \qquad ( 43 )$$
wherein, χ^{(k)} is the error index; μ^{(k)} symbolizes unbalanced power acquired form power flow calculation after k^{th} reactive power optimization; μ^{best} is the minimum unbalanced power ever recorded in history;
when μ^{(k)} breaks the best record μbest, step size is enlarged and μ^{best} is updated; otherwise, it is reduced as shown (44)-(47);
$${\underline{{ϕ}_{i}}}^{V ( k + 1 )} = \{ \begin{matrix}{η}_{1} {\underline{{ϕ}_{i}}}^{V ( k )} ( {χ}^{( k )} > 0 ) \\ max ( {η}_{2} {\underline{{ϕ}_{i}}}^{V ( k )} , {V}_{i}^{min} - {V}_{i} ) ( {χ}^{( k )} \leq 0 )\end{matrix} \qquad ( 44 )$$
$${\overline{{ϕ}_{i}}}^{V ( k + 1 )} = \{ \begin{matrix}{η}_{1} {\overline{{ϕ}_{i}}}^{V ( k )} ( {χ}^{( k )} > 0 ) \\ min ( {η}_{2} {\overline{{ϕ}_{i}}}^{V ( k )} , {V}_{i}^{max} - {V}_{i} ) ( {χ}^{( k )} \leq 0 )\end{matrix} \qquad ( 45 )$$
$${\underline{{ϕ}_{i}}}^{Q ( k + 1 )} = \{ \begin{matrix}{η}_{1} {\underline{{ϕ}_{i}}}^{Q ( k )} ( {χ}^{( k )} > 0 ) \\ max ( {η}_{2} {\underline{{ϕ}_{i}}}^{Q ( k )} , {Q}_{i}^{min} - {Q}_{i} ) ( {χ}^{( k )} \leq 0 )\end{matrix} \qquad ( 46 )$$
$${\overline{{ϕ}_{i}}}^{Q ( k + 1 )} = \{ \begin{matrix}{η}_{1} {\overline{{ϕ}_{i}}}^{Q ( k )} ( {χ}^{( k )} > 0 ) \\ min ( {η}_{2} {\overline{{ϕ}_{i}}}^{Q ( k )} , {Q}_{i}^{max} - {Q}_{i} ) ( {χ}^{( k )} \leq 0 )\end{matrix} \qquad ( 47 )$$
wherein,
$${\underline{{ϕ}_{i}}}^{V} , {\overline{{ϕ}_{i}}}^{V}$$
are optimization step upper and lower limit for voltage magnitude at generation bus I;
$${\underline{{ϕ}_{i}}}^{G} , {\overline{{ϕ}_{i}}}^{G}$$
are optimization step upper and lower limit for reactive power injection at generation bus I; k is the number of iterations and χ^{(k)} is the error index, η₁ and η₂ are step adjustment parameters that satisfy 0<η₁<1<η₂, Vᵢ is voltage magnitude at bus I,
$${V}_{i}^{max} and {V}_{i}^{min}$$
are maximum and minimum voltage magnitudes at bus I, Qᵢ is reactive power injection at bus I,
$${Q}_{i}^{max} and {Q}_{i}^{min}$$
are upper and lower limits of Qᵢ at generation bus I.

6. The method according to claim 2, wherein the method comprises solution of available transfer capability based on continuation power flow:
as shown in (3), λ=0 represents original load and generation status; Power flow equations, or (3), is regarded as parameterized equation about λ, whose geometric meaning is a curve in the solution space shown in (48):
$$F ( Y ) = F ( X , λ ) = 0 ( Y = [ \begin{matrix}\begin{matrix}\begin{matrix}μ & θ\end{matrix} & V\end{matrix} & λ\end{matrix} ] ) \qquad ( 48 )$$
to discover the limit of power flow transition, trace along with the curve according to continuation power flow, through repetitive predictor and corrector steps, enlarging λ, so as to get voltage stability limit;
before continuation power flow calculation, power growth mode of load and generation should be given in advance, with sum of
$${K}_{i}^{P} and {K}_{i}^{Q}$$
being 0, respectively as demonstrated in (49):
$$K = {[ \begin{matrix}\begin{matrix}\begin{matrix}\begin{matrix}\begin{matrix}\begin{matrix}\begin{matrix}{K}_{1}^{P} & {K}_{2}^{P}\end{matrix} & L\end{matrix} & {K}_{NB}^{P}\end{matrix} & {K}_{1}^{Q}\end{matrix} & {K}_{2}^{Q}\end{matrix} & L\end{matrix} & {K}_{NB}^{Q}\end{matrix} ]}^{T} \qquad ( 49 )$$
$$( {\sum }_{i = 1}^{N B} {K}_{i}^{P} = 0 ; {\sum }_{i = 1}^{N B} {K}_{i}^{Q} = 0 )$$
wherein, μ is the level of system unbalance power, θ is the vector of voltage phase angles except for the slack bus; V is the vector of voltage magnitudes, λ represents power incremental parameter, Y symbolizes continuation power flow solution vector,
$${K}_{i}^{P} and {K}_{i}^{Q}$$
are active and reactive power increase coefficients for the bus i relative to λ, NB is the total bus count of the network.

7. The method according to claim 1, wherein the method comprises predictor-corrector steps, calculation method of predictor steps is below:
$${Y}^{pre} = {Y}^{base} + σ \frac{dY}{{‖ dY ‖}_{2}} \qquad ( 50 )$$
$$\{ \begin{matrix}{{J}_{CPF} [ dY ]}^{T} = [ \begin{matrix}0 \\ 1\end{matrix} ] \\ {J}_{CPF} = [ \begin{matrix}\begin{matrix}{J}_{PF} & K\end{matrix} \\ {e}_{c}\end{matrix} ]\end{matrix} \qquad ( 51 )$$
$$( {e}_{c} = [ \begin{matrix}0 & L & 0 & 1 & 0 & L & 0\end{matrix} ] ; c = \{ c ‖ {dy}_{c} \vert = {‖ dY ‖}_{∞} \} )$$
wherein, Y^{base} is original continuation power flow solution, and Y^{pre} represents the solution to be predicted, o is step-size control coefficient, dY is tangent predictor vector, and ∥dY∥₂ is the second norm of dY; dY/∥dY∥₂ is the normalization of predictor step, thus σ represents actual step size regardless the modulus of dY, J_{CPF} marks the Jacobian matrix for continuation power flow calculation, J_{PF} symbolizes the Jacobian matrix for power flow calculation, K is the vector consisting of
$${K}_{i}^{P} and {K}_{i}^{Q} ,$$
e_{c} is a vector for which the cth element is 1 while others are 0;
recognition of bifurcation: bifurcation is a sign where power system reaches voltage stability limit as the increase of λ, including two criterions, saddle node bifurcation and limit induced bifurcation;
saddle node bifurcation represents the situation where λ is unable to increase further, whose criterion is dλ<0;
limit induced bifurcation represents the situations where system reactive power reservation is exhausted, whose criterion is that there exists a bus whose VQ sensitivity is negative; if there exists at least one bus whose voltage magnitude declines along with the increase of reactive power injection, system voltage is unstable; calculation method of minimum VQ sensitivity for each bus is listed in (52):
$${δ}^{min} = min \{ {δ}_{i} \vert δ = {diag ( {J}_{CPF} )}^{- 1} , i ∈ {Φ}^{L} \} > 0 \qquad ( 52 )$$
wherein, δᵢ is the VQ sensitivity of bus I; δ represents the vector of VQ sensitivity, which is also the diagonal elements of (J_{CPF})⁻¹; δ^{min} is the minimum VQ sensitivity of all buses; Φ^{L} is the subset of load buses;
corrector: corrector steps are as follows:
due to the nonlinear feature of the curve, predicted solution is not on the curve F(Y), which requires local parameterization to get power flow solution as shown in (53);
$$G ( Y ) = \{ \begin{matrix}F ( Y ) = 0 \\ {y}_{c} - {y}_{c}^{pre} = 0\end{matrix} \qquad ( 53 )$$
wherein, Y symbolizes continuation power flow solution vector; G is the equation set of continuation power flow; y_{c} is the prolonged factor and
$${y}_{c}^{p r e}$$
is y_{c} obtained from predictor steps;
solution of (53) is similar with power flow calculation, as shown in (54), whose convergence criterion is given in (55):
$$\{ \begin{matrix}{G ( {Y}^{( s )} ) = ( {J}_{CPF} \vert}_{Y = {Y}^{( s )}} ) {( Δ {Y}^{( s )} )}^{T} = {{J}_{CPF}^{( s )} ( Δ {Y}^{( s )} )}^{T} \\ {Y}^{( s + 1 )} = {Y}^{( s )} + Δ {Y}^{( s )}\end{matrix} \qquad ( 54 )$$
$${ε}^{CPF} = {‖ G ( Y ) ‖}_{∞} \qquad ( 55 )$$
wherein, Y symbolizes continuation power flow solution vector; G is the equation set of continuation power flow; s and (s+1) represent the number of iterations; Y^{(s)} the value of Y in s^{th} iteration; J_{CPF} marks the Jacobian matrix for continuation power flow calculation; ε^{CPF} is the infinite norm of G(X);
select the number of iterations in corrector steps as the reference of adjusting step size σ, as shown in (56);
$$σ = \{ \begin{matrix}{β}_{1} σ & ( sc > ξ ) \\ {β}_{2} σ & ( sc \leq ξ )\end{matrix} \qquad ( 56 )$$
wherein, sc is the number of iterations; ξ is a threshold concerning enlarging of decreasing step size; β₁ and β₂ are constants that satisfy 0<β₁<1<β₂.

8. The method according to claim 1, wherein a computer device comprises a memory and a processor, wherein the memory stores a computer program, and the processor executes the computer program to implement the steps of available transfer capability calculation method considering reactive power support.

9. A solving system of available transfer capability calculation considering reactive power support, comprising:
power flow modeling and solving module, configured as: modeling and solving power flow equations:
establishment of reactive power optimization modeling module, configured as: establish reactive power optimization model based on mixed integer linear programming, including: power system voltage regulation consists of adjusting reactive power injection of generators, changing transformer taps and switching capacitors; the object of reactive power optimization is to get best voltage support by adjusting three types of control variables: adjusting reactive power injection of generators, changing transformer taps and switching capacitors;
available transfer capability calculation module, configured as: solving available transfer capability based on continuation power flow;
solve available transfer capability by continuation power flow;
modeling and solving power flow equations comprises:
acquiring improved power flow formulations, as shown below:
$$\{ \begin{matrix}\begin{matrix}{f}^{P} = \{ {P}_{i} - {\sum }_{j = 1}^{N B} {V}_{i} {V}_{j} ( {G}_{ij} cos {θ}_{ij} + {B}_{ij} sin {θ}_{ij} ) = 0 & ( i ∈ {Φ}^{Bus} )\end{matrix} \\ \begin{matrix}{f}^{Q} = \{ {Q}_{i} - {\sum }_{j = 1}^{N B} {V}_{i} {V}_{j} ( {G}_{ij} sin {θ}_{ij} - {B}_{ij} cos {θ}_{ij} ) = 0 & ( i ∈ {Φ}^{Bus} )\end{matrix}\end{matrix} \qquad ( 1 )$$
$$\{ \begin{matrix}{g}^{P} = \{ \begin{matrix}{P}_{i j}^{Bra} - {G}_{i j} ( {V}_{i}^{2} - {V}_{i} {V}_{j} cos {θ}_{i j} ) + {B}_{i j} {V}_{i} {V}_{j} sin {θ}_{i j} = 0 \\ ( ( i , j ) ∈ {Φ}^{Bra} )\end{matrix} \\ {g}^{Q} = \{ \begin{matrix}{Q}_{i j}^{Bra} - {B}_{i j} ( {V}_{i}^{2} - {V}_{i} {V}_{j} cos {θ}_{i j} ) + {G}_{i j} {V}_{i} {V}_{j} sin {θ}_{i j} = 0 \\ ( ( i , j ) ∈ {Φ}^{Bra} )\end{matrix}\end{matrix} \qquad ( 2 )$$
$$\{ \begin{matrix}{P}_{i} = {P}_{i 0} + μ {α}_{i} + λ {K}_{i}^{P} \\ {Q}_{i} = {Q}_{i 0} + λ {K}_{i}^{Q}\end{matrix} \qquad ( 3 )$$
wherein, f^{P} and f^{Q} represent active power and reactive power balance equations; g^{P} and g^{Q} represent equations for active power and reactive power of branches; Pᵢ and Qᵢ are active and reactive power injections at bus i, while Pᵢ₀ and Qᵢ₀ are Pᵢ and Qᵢ at initial PF state; Pᵢⱼ^{Bra} and Qᵢⱼ^{Bra} are active and reactive power flow carried by branch (i, j); Vᵢ is voltage magnitude at bus I; μ is the level of system unbalance power caused by power loss; αᵢ is AGC participating coefficient for generation bus i to handle the unbalance power; θᵢⱼ is the phase angle between complex bus voltages Vᵢ and Vⱼ; NB is the total bus count of the network; Gᵢᵢ and Bᵢᵢ are self-conductance and self-susceptance at bus I; Gᵢⱼ and Bᵢⱼ represent mutual conductance mutual susceptance between buses i and j; Φ^{Bus} represent collections of all system buses; Φ^{Bra} represent collections of all system branches; μ represents power incremental parameter, while
$${K}_{i}^{P} and {K}_{i}^{Q}$$
are active and reactive power increase coefficients for the bus i relative to λ;
an Auto Generation Control AGC participating coefficients are generally specified as constants which can be expressed as relation (4):
$$A = {[ \begin{matrix}{α}_{1} & {α}_{2} & L & {α}_{n}\end{matrix} ]}^{T} ( {\sum }_{i = 1}^{n} {α}_{i} = 1 ; {α}_{i} \geq 0 ) \qquad ( 4 )$$
wherein, A is the vector of unbalanced power proportion;
compact from of equation (1) can be expressed by:
$$F ( X ) = 0 ( X = [ μ , θ , V ] ) \qquad ( 5 )$$
wherein, θ is the vector of voltage phase angles except for the slack bus; V is the vector of voltage magnitudes;
equation (5) is a nonlinear equation set, which can be solved by iterative algorithms; Newton iterative relations shown in (6) are established;
$$\{ \begin{matrix}{F ( {X}^{( s )} ) = ( \frac{\partial F ( X )}{\partial X} \vert}_{X = {X}^{( s )}} ) {( Δ {X}^{( s )} )}^{T} = {{J}_{P F}^{( s )} ( Δ {X}^{( s )} )}^{T} \\ {X}^{( s + 1 )} = {X}^{( s )} - Δ {X}^{( s )}\end{matrix} \qquad ( 6 )$$
wherein, s and (s+1) represent the number of iterations; X^{(s)} the value of X in s^{th} iteration;
the structure of Jacobian matrix
$${J}_{P F}^{( s )}$$
in (6) is elaborated as shown in (7);
$${{J}_{PF}^{( s )} = ( \begin{matrix}A & \frac{\partial {f}^{P}}{\partial θ} & \frac{\partial {f}^{P}}{\partial V} \\ 0 & \frac{\partial {f}^{Q}}{\partial θ} & \frac{\partial {f}^{Q}}{\partial V}\end{matrix} ) \vert}_{X = {X}^{( s )}} \qquad ( 7 )$$
derivative of active power equations to unbalanced power is A; derivative of active and reactive power equations to phase angles and voltage magnitudes are shown in (8)-(11);
$$\frac{\partial {f}_{i}^{P}}{\partial {θ}_{j}} = \{ \begin{matrix}{V}_{i}^{2} {B}_{ii} + {Q}_{i} ( i = j ) \\ - {V}_{i} {V}_{j} ( {G}_{ij} sin {θ}_{ij} - {B}_{ij} cos {θ}_{ij} ) ( else )\end{matrix} \qquad ( 8 )$$
$$\frac{\partial {f}_{i}^{P}}{\partial {V}_{j}} = \{ \begin{matrix}- {V}_{i}^{2} {G}_{ii} - {P}_{i} ( i = j ) \\ - {V}_{i} {V}_{j} ( {G}_{ij} cos {θ}_{ij} - {B}_{ij} cos {θ}_{ij} ) ( else )\end{matrix} \qquad ( 9 )$$
$$\frac{\partial {f}_{i}^{Q}}{\partial {θ}_{j}} = \{ \begin{matrix}{V}_{i}^{2} {G}_{ii} - {P}_{i} ( i = j ) \\ {V}_{i} {V}_{j} ( {G}_{ij} cos {θ}_{ij} - B sin {θ}_{ij} ) ( else )\end{matrix} \qquad ( 10 )$$
$$\frac{\partial {f}_{i}^{Q}}{\partial {V}_{j}} = \{ \begin{matrix}{V}_{i}^{2} {B}_{ii} - {Q}_{i} ( i = j ) \\ - {V}_{i} {V}_{j} ( {G}_{ij} sin {θ}_{ij} - {B}_{ij} cos {θ}_{ij} ) ( else )\end{matrix} \qquad ( 11 )$$
wherein,
$${f}_{i}^{P} and {f}_{i}^{Q}$$
represent active power and reactive power balance equations of bus i; Pᵢ and Qᵢ are active and reactive power injections at bus i; Vᵢ is voltage magnitude at bus i; θᵢ symbolizes phase angel at bus i; θᵢⱼ is the phase angle between bus i and j; Gᵢᵢ and Bᵢᵢ are self-conductance and self-susceptance at bus i; Gᵢⱼ and Bᵢⱼ represent mutual conductance mutual susceptance between buses i and j;
convergence principle of Newton method is elaborated in (12);
$${ε}^{P F} = {‖ F ( X ) ‖}_{∞} \qquad ( 12 )$$
considering the infinite norm of F(X), ε^{PF}, when ε^{PF} is less than a minimum positive (ε^{PF}<ε^{min}), the Newton iterations converge; moreover, divergence takes place if ε^{PF} exceeds an allowable level (ε^{PF}>ε^{max}); ε^{min} and ε^{max} are parameters for judging convergence and divergence of Newton method.
